(19) United States
(12) Patent Application Publication
(10) Pub. No.: US 2026/0013367 A1
(43) Pub. Date: Jan. 8, 2026

(54) DISPLAY DEVICE, ELECTRONIC DEVICE INCLUDING THE DISPLAY DEVICE, AND METHOD OF MANUFACTURING THE DISPLAY DEVICE

(71) Applicant: Samsung Display Co., LTD., Yongin-si (KR)

(72) Inventors: KYUMIN KIM, Yongin-si (KR); SHINHYUK YANG, Yongin-si (KR); DONGHAN KANG, Yongin-si (KR); JEONG HWAN KIM, Yongin-si (KR); JEEHOON KIM, Yongin-si (KR); KAP SOO YOON, Yongin-si (KR); SUNG-HOON LIM, Yongin-si (KR)

(21) Appl. No.: 19/068,667

(22) Filed: Mar. 3, 2025

(30) Foreign Application Priority Data
Jul. 4, 2024 (KR) 10-2024-0088527

(51) Int. Cl. H10K 59/80; H10K 59/38; H10K 102/00; H10K 102/10

(52) U.S. Cl. CPC H10K 59/80518; H10K 59/38; H10K 2102/102; H10K 2102/103; H10K 2102/351

(57) ABSTRACT

A display device is provided. The display device includes a substrate including first and second pixel areas that are adjacent. The display device includes a via layer on the substrate defining first and second grooves overlapping the first and second pixel areas, respectively, and a depth of the first groove that is different from a depth of the second groove. The display device includes first and second pixel electrodes in the first and second grooves, respectively, the levels of upper surfaces of the pixel electrodes are higher than a level of any upper surface of the via layer and the thicknesses of the pixel electrodes are different. The display device includes a light emitting layer on the pixel electrodes.

### CROSS-REFERENCE TO RELATED APPLICATION

This application claims priority to and the benefit of Korean Patent Application No. 10-2024-0088527, filed on Jul. 4, 2024, in the Korean Intellectual Property Office, the entire disclosure of which is incorporated herein by reference.

### BACKGROUND

### 1. Field

One or more aspects of embodiments of the present disclosure relate to a display device and a method of manufacturing the same. For example, the present disclosure relates to a display device that provides visual information and a method of manufacturing the same.

### 2. Description of the Related Art

As uses for display devices become more diverse, interest in large display devices such as smartphones, large televisions, vehicle displays, and/or the like continues to increase. As intensive research is being conducted on enlarging developed display devices recently, luminance uniformity and luminance improvement technology are being developed.

For example, as one of technologies for improving brightness, a technology that amplifies intensity of emitted light using constructive interference is being studied. To this end, attempts are being made to selectively arrange pixel electrodes having generally different thicknesses to achieve constructive interference for each wavelength of light.

### SUMMARY

One or more aspects of embodiments of the present disclosure are directed toward a display device having improved display quality.

One or more aspects of embodiments of the present disclosure are directed toward a method of manufacturing a display device having improved display quality.

One or more aspects of embodiments of the present disclosure are directed toward an electronic device including the display device.

However, it should be noted that these objectives are merely examples, and the scope of the disclosure is not limited to the herein-mentioned aspects. Rather, other objectives of embodiments of the present disclosure will be apparent to those skilled in the art from the following descriptions.

A display device according to one or more embodiments of the present disclosure includes a substrate including a first pixel area and a second pixel area adjacent to the first pixel area, a via layer arranged on the substrate and defining (e.g., including) a first groove overlapping the first pixel area and having a first depth and a second groove overlapping the second pixel area and having a second depth different from the first depth. A first pixel electrode is arranged in the first groove of the via layer and a level of an upper surface of the first pixel electrode is higher than a level of an (e.g., any) upper surface of the via layer with respect to the substrate, a second pixel electrode arranged in the second groove of the via layer, having a thickness different from a thickness of the first pixel electrode, and a level of an upper surface of the second pixel electrode is higher than a level of an (e.g., any) upper surface of the via layer with respect to the substrate, and a light emitting layer arranged on the first pixel electrode and the second pixel electrode.

In one or more embodiments, the first pixel electrode may include a first lower electrode layer, a first reflective electrode layer, and a first upper electrode layer sequentially arranged on the substrate, and the second pixel electrode may include a second lower electrode layer, a second reflective electrode layer, and a second upper electrode layer sequentially arranged on the substrate.

In one or more embodiments, a thickness of the first upper electrode layer and a thickness of the second upper electrode layer may be different.

In one or more embodiments, with respect to the substrate, a level of an upper surface of the first upper electrode layer may be equal to a level of an upper surface of the second upper electrode layer (e.g., the levels may be substantially the same).

In one or more embodiments, the first upper electrode layer and the first lower electrode layer may each include substantially a same material.

In one or more embodiments, the first upper electrode layer and the second upper electrode layer may each include a transparent conductive oxide including at least one selected from among (e.g., the group consisting of) indium (In) and tin (Sn).

In one or more embodiments, the display device may further include a common electrode arranged on the light emitting layer and that may be or include a plate electrode.

In one or more embodiments, the display device may further include a first color conversion layer arranged on the common electrode, overlapping the first pixel electrode (e.g., in a plan view), and converting light emitted from the light emitting layer into a light having a first color and a second color conversion layer arranged on the common electrode, overlapping the second pixel electrode (e.g., in a plan view), and converting (configured to convert) light emitted from the light emitting layer into a light having a second color, second color being different from the first color.

In one or more embodiments, a resonance distance between the common electrode and the first reflective electrode layer may satisfy Equation 1:

$$L = ( λ / 2 ) \times N . \qquad Equation 1$$

In Equation 1, L is the resonance distance, λ is a median value of a wavelength band of the first color, and N is a natural number

In one or more embodiments, a thickness of the first lower electrode layer may be equal to and a thickness of the second lower electrode layer (e.g., the thicknesses may be substantially the same).

In one or more embodiments, the via layer may define or include a first contact hole exposed by the first groove and penetrating the via layer and a second contact hole exposed by the second groove, penetrating the via layer, and having a depth different from a depth of the first contact hole.

In one or more embodiments, the first reflective electrode layer of the first pixel electrode may extend into the first contact hole, and the second reflective electrode layer of the second pixel electrode may extend into the second contact hole.

A method of manufacturing the display device according to one or more embodiments of the present disclosure includes forming a via layer on a substrate that includes a first pixel area and a second pixel area adjacent to the first pixel area. The method includes forming with (using) a halftone mask, a first groove and a second groove, the first groove having a first depth in the via layer overlapping the first pixel area and the second groove having a second depth in the via layer overlapping the second pixel area, the second depth being different from the first depth. The method includes forming a preliminary lower electrode layer on the via layer, forming a preliminary reflective electrode layer on the preliminary lower electrode layer, forming a preliminary upper electrode layer on the preliminary reflective electrode layer which has a surface level that is higher than a level of an (e.g., any) upper surface of the via layer, and patterning the preliminary lower electrode layer, the preliminary reflective electrode layer, and the preliminary upper electrode layer to form a first pixel electrode in the first pixel area and a second pixel electrode in the second pixel area.

In one or more embodiments, the half tone mask may include a first semi-transmissive portion and a second semi-transmissive portion that transmit a portion of light, a first transmissive portion and a second transmissive portion that transmit all light, and light blocking part that blocks all light, and a transmittance of the first semi-transmissive portion of the halftone mask corresponding to the first groove may be different from a transmittance of the second semi-transmissive portion of the halftone mask corresponding to the second groove

In one or more embodiments, the method may further include, in forming with the halftone mask the first groove and the second groove, forming a first contact hole exposed by the first groove (e.g., in a plan view) and penetrating the via layer and a second contact hole exposed by the second groove (e.g., in a plan view), penetrating the via layer, and having a depth different from a depth of the first contact hole

In one or more embodiments, the first contact hole may be formed through the first transmissive portion (e.g., part of the halftone mask corresponding to the first groove), and the second contact hole may be formed through the second transmissive portion (e.g., part of the halftone mask corresponding to the second groove).

In one or more embodiments, the first groove and the first contact hole may be formed simultaneously, and the second groove and the second contact hole may be formed simultaneously

In one or more embodiments, the method may further include, after forming the first pixel electrode and the second pixel electrode, forming a light emitting layer on the first pixel electrode and the second pixel electrode with (or by using) an open mask.

In one or more embodiments, forming the preliminary upper electrode layer may include forming the preliminary upper electrode layer through a solution process method.

The display device according to one or more embodiments of the present disclosure may include a substrate including a first pixel area and a second pixel area adjacent to the first pixel area, a via layer arranged on the substrate and defining a first groove overlapping the first pixel area and having a first depth and a second groove overlapping the second pixel area and having a second depth different from the first depth, a first pixel electrode arranged in the first groove of the via layer and a level of an upper surface of the first pixel electrode is higher than a level of any upper surface of the via layer with respect to the substrate, a second pixel electrode arranged in the second groove of the via layer, having a thickness different from a thickness of the first pixel electrode, and a level of an upper surface of the second pixel electrode is higher than a level of any upper surface of the via layer with respect to the substrate, and a light emitting layer arranged on the first pixel electrode and the second pixel electrode.

Accordingly, by forming the grooves at different depths, luminous efficiency may be increased due to constructive interference with a light emitted by each pixel. In some embodiments, when forming the pixel electrodes, a manufacturing process of the pixel electrodes may be simplified and manufacturing costs may be reduced by etching them all at once using a halftone mask after a solution process.

An electronic device according to one or more embodiments of the present disclosure includes the preceding display device as described herein. In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

### BRIEF DESCRIPTION OF THE DRAWINGS

The accompanying drawings are included to provide a further understanding of the preceding and other aspects and features of certain embodiments of the present disclosure and are incorporated in and constitute a part of this specification. The drawings illustrate example embodiments that will be more apparent when taken together with the description. In the drawings:

FIG. 1 is a perspective view of a display device according to one or more embodiments of the present disclosure.

FIG. 2 is a plan view showing divided pixel areas of the display device of FIG. 1 according to one or more embodiments of the present disclosure.

FIG. 3 is a cross-sectional view showing one or more embodiments of the display device of FIG. 2 cut along line I-I′ according to one or more embodiments of the present disclosure.

FIG. 4 is an enlarged cross-sectional view of the pixel electrodes of FIG. 3 according to one or more embodiments of the present disclosure.

FIG. 5 is an enlarged cross-sectional view showing the first pixel electrode, the light emitting layer, and the common electrode of FIG. 3 according to one or more embodiments of the present disclosure.

FIG. 6 is a plan view showing an example of the via layer of FIG. 3 according to one or more embodiments of the present disclosure.

FIGS. 7-28 are cross-sectional views showing a method of manufacturing the display device of FIG. 3 according to one or more embodiments of the present disclosure.

FIG. 29 is a block-diagram showing an embodiment of an electronic device including the display device of FIG. 1.

FIG. 30 is a perspective view showing an embodiment of the electronic device of FIG. 29.

### DETAILED DESCRIPTION

Reference will now be made in more detail to embodiments, examples of which are illustrated in the accompanying drawings, wherein like reference numerals refer to like elements throughout. Regarding embodiments of the present disclosure disclosed in this text, specific structural and functional descriptions are merely illustrative for a purpose of explaining the embodiments of the present disclosure, and the embodiments of the present disclosure may be implemented in one or more suitable forms and should not be construed as limited to the embodiments described in. Rather, these embodiments are provided so that this disclosure will be thorough and complete, and will fully convey the scope of the present disclosure to those skilled in the art.

Because the present disclosure may be subject to one or more suitable changes and may have one or more suitable forms, example embodiments will be illustrated in the drawings and described in more detail in the text. However, this is not intended to limit the present disclosure to a specific disclosed form, and should be understood to include all changes, equivalents, and substitutes included in the spirit and technical scope of the present disclosure.

Terms such as first, second, and/or the like may be used to describe one or more suitable components, but the components should not be limited by the terms. The preceding terms may be used for a purpose of distinguishing one component from another component. For example, a first component may be referred to as a second component, and similarly, the second component may be referred to as a first component without departing from the scope of the present disclosure.

It will be understood that when an element is referred to as being “connected” or “coupled” to another element, it may be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” and/or the like).

The terminology used herein is for a purpose of describing particular example embodiments only and is not intended to be limiting of the present inventive concept. As used herein, the singular forms “a,” “an” and “the” are intended to include plural forms as well, unless the context clearly indicates otherwise. It will be further understood that the terms “comprises” “comprise,” “comprising,” “includes,” “include,” “including,” “has,” “have,” and “having” and/or the like, when used in this specification, specify a presence of stated features, integers, steps, operations, elements, and/or components, but do not preclude the presence or addition of one or more other features, integers, steps, operations, elements, components, and/or groups thereof.

Terms such as “below”, “at the bottom”, “lower”, “below”, “above”, “on top”, “on the top”, “on”, and/or the like are used to explain a relationship between components shown in the drawings. The terms are relative concepts and are explained based on the direction indicated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Unless otherwise defined, all terms (including chemical, technical and scientific terms) used herein have a same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Hereinafter, embodiments will be described in more detail with reference to the accompanying drawings. Same reference numerals are used for same components in the drawings, and redundant descriptions of same components may not be repeated. Sizes of elements in the drawings may be exaggerated for convenience of explanation. Because sizes and thicknesses of components in the drawings may be arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In this context, “consisting essentially of” indicates that any additional components will not materially affect the chemical, physical, optical or electrical properties of the semiconductor film.

Further, in this specification, the phrase “plan view,” indicates viewing a target portion from the top, and the phrase “on a cross-section” indicates viewing a cross-section formed by vertically cutting a target portion from the side.

In this specification, a plane may be defined by a first direction D1 and a second direction D2 that crosses (e.g., intersects) the first direction D1. For example, the second direction D2 may be perpendicular to the first direction D1. In some embodiments, a third direction D3 may be a normal direction of the plane. For example, the third direction D3 may be perpendicular to the plane formed by the first direction D1 and the second direction D2.

### Display Device

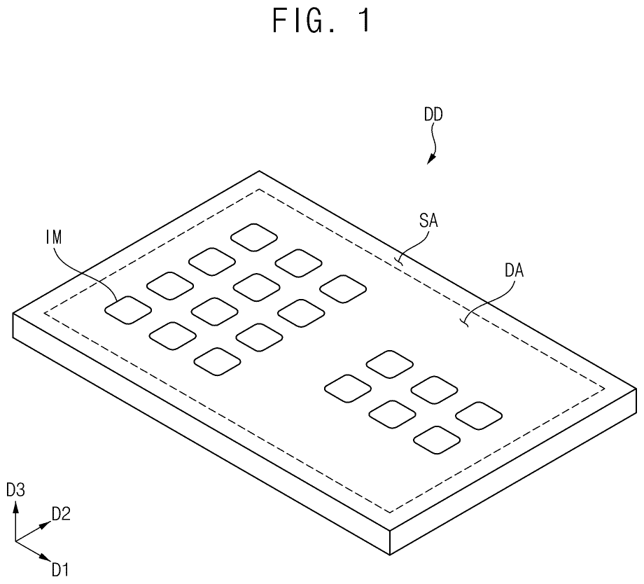

FIG. 1 is a perspective view of a display device according to one or more embodiments of the present disclosure.

Referring to FIG. 1, a display device DD may include a display area DA and a peripheral area SA. The display area DA may be at least partially surrounded by the peripheral area SA. The display area DA may be an area that may display an image by generating light or adjusting a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM. Users may receive information from the display device DD through the plurality of images IM.

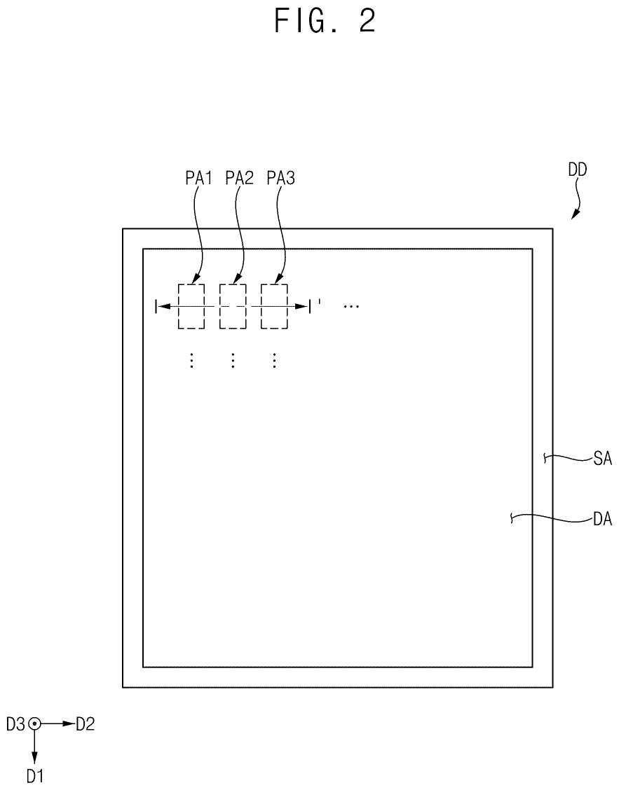

FIG. 2 is a plan view showing divided pixel areas of the display device of FIG. 1.

Referring to FIG. 2, a first pixel area PA1, a second pixel area PA2, and a third pixel area PA3 may be defined in the display area DA of the display device DD. The first pixel area PA1, the second pixel area PA2, and the third pixel area PA3 may be arranged side by side in the second direction D2. For example, the second pixel area PA2 may be defined adjacent to the first pixel area PA1 in the second direction D2, and the third pixel area PA3 may be adjacent to the second pixel area PA2. However, embodiments of the present disclosure are not necessarily limited thereto. The first pixel area PA1, the second pixel area PA2, and the third pixel area PA3 may also be defined in a mattress shape in the first direction D1 and/or the second direction D2.

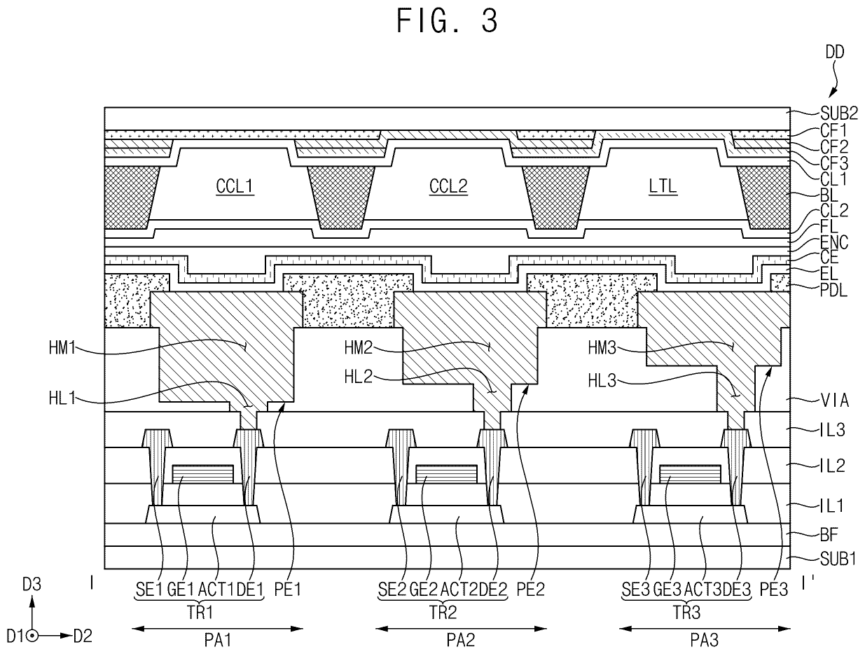

FIG. 3 is a cross-sectional view showing one or more embodiments of the display device of FIG. 2 cut along line I-I′.

Referring to FIGS. 2 and 3, the display device DD may include a first substrate SUB1, a buffer layer BF, first, second, and third insulating layers IL1, IL2, and IL3, first, second, and third transistors TR1, TR2, and TR3, via layer VIA, pixel electrodes PE1, PE2, and PE3, pixel defining layer PDL, light emitting layer EL, common electrode CE, encapsulation layer ENC, filling layer FL, first and second capping layers CL1, CL2, color conversion layers CCL1, CCL2, light transmitting layer LTL, light blocking member BL, color filters CF1, CF2, and CF3, and a second substrate SUB2.

The first, second, and third transistors TR1, TR2, and TR3 may include first, second, and third active layers ACT1, ACT2, and ACT3, first, second, and third gate electrodes GE1, GE2, and GE3, first, second, and third source electrodes SE1, SE2, and SE3 and first, second, and third drain electrodes DE1, DE2, and DE3, respectively.

First, a structure of the first substrate SUB1 to the encapsulation layer ENC will be described sequentially.

The first substrate SUB1 may include a transparent material or an opaque material. The first substrate SUB1 may be made of a transparent resin substrate. Examples of the transparent resin substrate may include a polyimide substrate. In some embodiments, the polyimide substrate may include a first organic layer, a first barrier layer, a second organic layer, and/or the like. Optionally, the first substrate SUB1 may be a quartz substrate, a synthetic quartz substrate, a calcium fluoride substrate, a fluorine-doped quartz substrate, a soda lime glass substrate, a non-alkali glass substrate, and/or the like. These may be used alone or in combination with each other.

The buffer layer BF may be arranged on the first substrate SUB1. The buffer layer BF may prevent metal atoms or impurities from diffusing from the first substrate SUB1 to the first, second, and third transistors TR1, TR2, and TR3. In some embodiments, the buffer layer BF may improve a flatness of a surface of the first substrate SUB1 when a surface of the first substrate SUB1 is not uniform. For example, the buffer layer BF may include an inorganic material such as silicon oxide, silicon nitride, and/or silicon oxynitride. These may be used alone or in combination with each other.

The first, second, and third active layers ACT1, ACT2, and ACT3 may be arranged on the buffer layer BF. Each of the first, second, and third active layers ACT1, ACT2, and ACT3 may include a metal oxide semiconductor, an inorganic semiconductor (e.g., amorphous silicon, poly silicon), or an organic semiconductor. However, embodiments of the present disclosure are not necessarily limited thereto. Each of the first, second, and third active layers ACT1, ACT2, and ACT3 may include a source region, a drain region, and a channel region arranged between the source region and the drain region. The first, second, and third active layers ACT1, ACT2, and ACT3 may be formed through substantially the same process and may include substantially the same material.

The first, second, and third active layers ACT1, ACT2, and ACT3 may be arranged in the first, second, and third pixel areas PA1, PA2, and PA3, respectively. For example, the first active layer ACT1 may be arranged in the first pixel area PA1. The second active layer ACT2 may be arranged in the second pixel area PA2. The third active layer ACT3 may be arranged in the third pixel area PA3.

The first insulating layer IL1 may be arranged on the buffer layer BF. For example, the first insulating layer IL1 may cover the first, second, and third active layers ACT1, ACT2, and ACT3 and may be arranged on the buffer layer BF. For example, the first insulating layer IL1 may include an inorganic insulating material.

The first, second, and third gate electrodes GE1, GE2, and GE3 may be arranged on the first insulating layer IL1. The first gate electrode GE1 may overlap a channel area of the first active layer ACT1, the second gate electrode GE2 may overlap a channel area of the second active layer ACT2, and the gate electrode GE3 may overlap a channel region of the third active layer ACT3.

Each of the first, second, and third gate electrodes GE1, GE2, and GE3 may include metal, alloy metal nitride, conductive metal oxide, transparent conductive material, and/or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), and/or the like. Examples of the conductive metal oxide may include indium tin oxide and indium zinc oxide. In some embodiments, examples of the metal nitride may include aluminum nitride (AlNx), tungsten nitride (WNx), and/or chromium nitride (CrNx). These may be used alone or in combination with each other. The first, second, and third gate electrodes GE1, GE2, and GE3 may be formed through substantially the same process and may include substantially the same material.

The second insulating layer IL2 may be arranged on the first insulating layer IL1. For example, the second insulating layer IL2 may cover the first, second, and third gate electrodes GE1, GE2, and GE3 and may be arranged on the first insulating layer IL1. The second insulating layer IL2 may include substantially the same material as the first insulating layer IL1.

The first, second, and third source electrodes SE1, SE2, and SE3 and the first, second, and third drain electrodes DE1, DE2, and DE3 may be arranged on the second insulating layer IL2. For example, each of the first source electrode SE1 and the first drain electrode DE1 may penetrate the first insulating layer IL1 and the second insulating layer IL2 and may be electrically connected to the first active layer ACT1. Each of the second source electrode SE2 and the second drain electrode DE2 may penetrate the first insulating layer IL1 and the second insulating layer IL2 and may be electrically connected to the second active layer ACT2. Each of the third source electrode SE3 and the third drain electrode DE3 may penetrate the first insulating layer IL1 and the second insulating layer IL2 and may be electrically connected to the third active layer ACT3. The first, second, and third source electrodes SE1, SE2, and SE3 and the first, second, and third drain electrodes DE1, DE2, and DE3 may include a conductive metal material.

The third insulating layer IL3 may be arranged on the second insulating layer IL2. For example, the third insulating layer IL3 may cover the first, second, and third source electrodes SE1, SE2, and SE3 and the first, second, and third drain electrodes DE1, DE2, and DE3 and may be arranged on the second insulating layer IL2. The third insulating layer IL3 may include substantially the same material as the first insulating layer IL1.

The via layer VIA may be arranged on the third insulating layer IL3. The via layer VIA may include an organic insulating material. The via layer VIA may be formed only in the display area DA and a portion of the peripheral area SA adjacent to the display area DA.

In one or more embodiments, grooves HM1, HM2, and HM3 may be defined (e.g., included) in the via layer VIA. The grooves HM1, HM2, and HM3 may be defined (e.g., included) by etching a portion of an upper surface of the via layer VIA. For example, the grooves HM1, HM2, and HM3 may have a concave bowl shape in a cross-sectional view on an upper surface of the via layer VIA.

For example, the first groove HM1 may be defined (e.g., included) in the first pixel area PA1, the second groove HM2 may be defined (e.g., included) in the second pixel area PA2, and the third groove HM3 may be defined (e.g., included) in the third pixel area PA3. However, embodiments of the present disclosure are not necessarily limited thereto. The third groove HM3 may not be included (e.g., be omitted). For example, the first groove HM1 may be defined (e.g., included) in an area that overlaps the first pixel area PA1, and the second groove HM2 may be defined (e.g., included) in an area that overlaps the second pixel area PA2. The via layer VIA may have flat surface in an area overlapping the third pixel area PA3 and the third groove HM3 may be undefined (e.g., the third groove HM3 may not be defined in the flat surface of the via layer VIA overlapping the third pixel area PA3).

In one or more embodiments, depths of each of the grooves HM1, HM2, and HM3 may be different. For example, the first groove HM1 may have a first depth DT1, the second groove HM2 may have a second depth DT2, and the third groove HM3 may have a third depth DT3 in the via layer VIA. For example, as shown in FIG. 3, the first depth DT1 may be deeper than the second depth DT2, and the second depth DT2 may be deeper than the third depth DT3. However, embodiments of the present disclosure are not necessarily limited thereto.

In one or more embodiments, contact holes may be defined (e.g., included) in the via layer VIA. The contact holes may include a first contact hole HL1, a second contact hole HL2, and a third contact hole HL3. The contact holes may overlap the grooves HM1, HM2, and HM3 of the via layer VIA in a plan view and may penetrate the via layer VIA.

The contact holes may penetrate a portion of the via layer VIA and the third insulating layer IL3 to expose upper surfaces of each of the first, second, and third drain electrodes DE1, DE2, and DE3. For example, the first contact hole HL1 may be defined under the first groove HM1 and expose an upper surface of the first drain electrode DE1. The second contact hole HL2 may be defined under the second groove HM2 and may expose an upper surface of the second drain electrode DE2. The third contact hole HL3 may be defined under the third groove HM3 and may expose an upper surface of the third drain electrode DE3.

In one or more embodiments, cross-sectional depths of the first contact hole HL1, the second contact hole HL2, and the third contact hole HL3 may be different. For example, as the cross-sectional depths of the first, second, and third grooves HM1, HM2, and HM3 are different, the depths of each of the first, second, and third contact holes HL1, HL2, and HL3 may be different.

Each of the first, second, and third pixel electrodes PE1, PE2, and PE3 may be arranged on the via layer VIA. For example, the first, second, and third pixel electrodes PE1, PE2, and PE3 may overlap the first, second, and third pixel areas PA1, PA2, and PA3 respectively and may be arranged on the via layer VIA. For example, the first pixel electrode PE1 may be arranged in the first groove HM1 and the first contact hole HL1 of the via layer VIA. The second pixel electrode PE2 may be arranged in the second groove HM2 and the second contact hole HL2 of the via layer VIA. The third pixel electrode PE3 may be arranged in the third groove HM3 and the third contact hole HL3 of the via layer VIA.

In one or more embodiments, with respect to the first substrate SUB1, levels of upper surfaces of the first pixel electrode PE1, the second pixel electrode PE2, and the third pixel electrode PE3 may be substantially the same. For example, although the first depth DT1, the second depth DT2, and the third depth DT3 are different, but each level of the upper surfaces of each of the first, second, and third pixel electrodes PE1, PE2, and PE3 may be substantially the same. Accordingly, thicknesses of each of the first pixel electrode PE1, the second pixel electrode PE2, and the third pixel electrode PE3 may be different from each other in a cross-sectional view.

The pixel defining layer PDL may be arranged on the first, second, and third pixel electrodes PE1, PE2, and PE3. For example, the pixel defining layer PDL may expose at least a portion of an upper surface of each of the first, second, and third pixel electrodes PE1, PE2, and PE3. The pixel defining layer PDL may include an inorganic insulating material or an organic insulating material.

The light emitting layer EL may be arranged on the pixel electrodes PE1, PE2, and PE3. The light emitting layer EL may also be arranged on the pixel defining layer PDL. For example, the light emitting layer EL may be continuously arranged on the first, second, and third pixel electrodes PE1, PE2, and PE3 and the pixel defining layer PDL.

In one or more embodiments, the light emitting layer EL may be an organic light emitting layer or an inorganic light emitting layer. For example, the light emitting layer EL may be to emit white light. For example, the light-emitting layer EL may be to emit white light by stacking a red light-emitting material, a green light-emitting material, and a blue light-emitting material in a tandem structure. For another example, the light emitting layer EL may be to emit blue light. However, embodiments of the present disclosure are not necessarily limited thereto.

The common electrode CE may be arranged on the light emitting layer EL. The common electrode CE may be continuously arranged on the light emitting layer EL. For example, the common electrode CE may be a plate electrode. The common electrode CE may include a conductive material. The light emitting layer EL may be to emit light based on a voltage difference between the pixel electrodes PE1, PE2, and PE3 and the common electrode CE.

The encapsulation layer ENC may be arranged on the common electrode CE. The encapsulation layer ENC may include at least one inorganic encapsulation layer and/or at least one organic encapsulation layer. In one or more embodiments, the inorganic encapsulation layer and the organic encapsulation layer may be alternately arranged. For example, the organic encapsulation layer may include a cured polymer such as polyacrylate, epoxy resin, and/or silicone resin. For example, the inorganic encapsulation layer may include silicon oxide, silicon nitride, silicon carbide, aluminum oxide, tantalum oxide, hafnium oxide, zirconium oxide, titanium oxide, and/or the like.

The filling layer FL may be arranged on the encapsulation layer ENC. For example, the filling layer FL may be arranged between the first substrate SUB1 and the second substrate SUB2 in a cross-sectional view. For example, the filling layer FL may fill a space between the first substrate SUB1 and the second substrate SUB2. The filling layer FL may include a material that allows light to pass through. For example, the filling layer FL may include an organic material that allows light to pass through. Examples of materials that may be used in the filling layer FL may include silicone-based resin and epoxy-based resin. These may be used alone or in combination with each other. However, the present disclosure is not necessarily limited thereto.

Hereinafter, configurations sequentially stacked from the second substrate SUB2 to the second capping layer CL2 will be described. For example, configurations stacked from the second substrate SUB2 in a direction opposite to the third direction D3 will be described.

The second substrate SUB2 may transmit light emitted from the light emitting layer EL. For example, the second substrate SUB2 may be transparent to allow light to pass through. For example, the second substrate SUB2 may be made of a transparent resin substrate. The second substrate SUB2 may include an insulating material such as glass and/or plastic. Optionally, the second substrate SUB2 may include an organic polymer material such as polycarbonate (PC), polyethylene (PE), and/or polypropylene (PP). These may be used alone or in combination with each other. However, embodiments of the present disclosure are not necessarily limited thereto.

The color filters CF1, CF2, and CF3 may be arranged under the second substrate SUB2. Each of the color filters CF1, CF2, and CF3 may selectively transmit light having a suitable wavelength.

The first color filter CF1 may selectively transmit a first color light (e.g., red light). The first color filter CF1 may overlap the first pixel area PA1 and the light blocking member BL (e.g., in a plan view). In some embodiments, the first color filter CF1 may not overlap the second pixel area PA2 and the third pixel area PA3 (e.g., in a plan view).

The second color filter CF2 may selectively transmit a second color light (e.g., green light). The second color filter CF2 may overlap the second pixel area PA2 and the light blocking member BL in a plan view. In some embodiments, the second color filter CF2 may not overlap the first pixel area PA1 and the third pixel area PA3 in a plan view.

The third color filter CF3 may selectively transmit a third color light (e.g., blue light). The third color filter CF3 may overlap the third pixel area PA3 and the light blocking member BL in a plan view. In some embodiments, the third color filter CF3 may not overlap the first pixel area PA1 and the second pixel area PA2 in a plan view.

The first capping layer CL1 may be arranged under the color filters CF1, CF2, and CF3. The first capping layer CL1 may cover the color filters CF1, CF2, and CF3. The first capping layer CL1 may be arranged along profiles of the color filters CF1, CF2, and CF3. The first capping layer CL1 may prevent or reduce contamination of the color filters CF1, CF2, and CF3 by blocking external impurities. For example, the first capping layer CL1 may include an inorganic material such as silicon oxide, silicon nitride, and/or silicon oxynitride. These may be used alone or in combination with each other. However, embodiments of the present disclosure are not necessarily limited thereto.

The light blocking member BL may be arranged under the first capping layer CL1. The light blocking member BL may be arranged not to overlap the first, second, and third pixel areas PA1, PA2, and PA3. The light blocking member BL may expose at least a portion of one surface of the first capping layer CL1. The light blocking member BL may block light emitted from the light emitting layer EL from passing through the second substrate SUB2.

For example, the light blocking member BL may define a plurality of areas under the color filters CF1, CF2, and CF3 that overlap each of the first, second, and third pixel areas PA1, PA2, and PA3. The light blocking member BL may include an organic material. Each of the plurality of areas may be filled with the first color conversion layer CCL1, the second color conversion layer CCL2, and the light transmissive layer LTL. For example, the display device DD may be a quantum dot display including the first color conversion layer CCL1, the second color conversion layer CCL2, and the light transmissive layer LTL. However, the present disclosure is not necessarily limited thereto.

The first color conversion layer CCL1 may be arranged to overlap the first pixel area PA1 in a plan view. The first color conversion layer CCL1 may include first quantum dots which are excited by light emitted from the light emitting layer EL and emit first color light (e.g., red light), first scattering particles, and a first photosensitive polymer.

The second color conversion layer CCL2 may be arranged to overlap the second pixel area PA2 in a plan view. The second color conversion layer CCL2 may include second quantum dots which are excited by light emitted from the light emitting layer EL and emit light of a second color (e.g., green light), second scattering particles, and a second photosensitive polymer.

The light transmissive layer LTL may be arranged to overlap the third pixel area PA3 in a plan view. The light transmissive layer LTL may emit blue light by transmitting light emitted from the light emitting layer EL. The light transmissive layer LTL may include a third photosensitive polymer.

The second capping layer CL2 may be arranged under the light blocking member BL, the first color conversion layer CCL1, the second color conversion layer CCL2, and the light transmissive layer LTL. As shown in FIG. 3, the second capping layer CL2 may be arranged according to a profile of each of a light blocking member BL, the first color conversion layer CCL1, the second color conversion layer CCL2, and the light transmission layer LTL. The second capping layer CL2 may prevent moisture, and/or the like from flowing into the first color conversion layer CCL1, the second color conversion layer CCL2, and the light transmissive layer LTL. For example, the second capping layer CL2 may include an inorganic material such as silicon oxide, silicon nitride, and/or silicon oxynitride. These may be used alone or in combination with each other. However, embodiments of the present disclosure are not necessarily limited thereto.

However, although the display device DD of the present disclosure is limited to an organic light emitting display device (OLED), the configuration of the present disclosure is not necessarily limited thereto. In other embodiments, the display device DD may also include a liquid crystal display device (LCD), a field emission display device (FED), a plasma display device (PDP), and/or an electrophoretic display device (EPD).

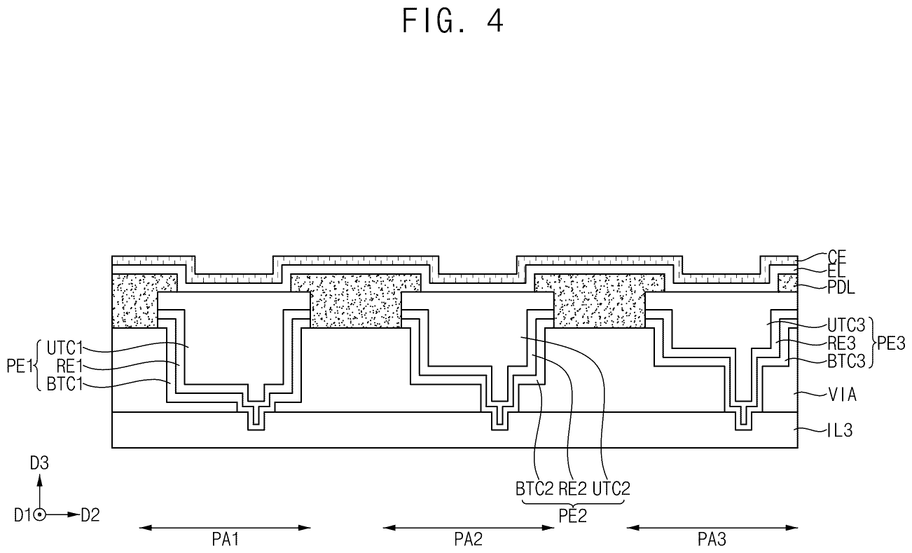

FIG. 4 is an enlarged cross-sectional view of the pixel electrodes of FIG. 3.

Referring to FIGS. 3 and 4, the first pixel electrode PE1 may include a first lower electrode layer BTC1, a first reflective electrode layer RE1, and a first upper electrode layer UTC1. The first reflective electrode layer RE1 may be arranged on the first lower electrode layer BTC1, and the first upper electrode layer UTC1 may be sequentially arranged on the first reflective electrode layer RE1.

The second pixel electrode PE2 may include a second lower electrode layer BTC2, a second reflective electrode layer RE2, and a second upper electrode layer UTC2. The second reflective electrode layer RE2 may be arranged on the second lower electrode layer BTC2, and the second upper electrode layer UTC2 may be sequentially arranged on the second reflective electrode layer RE2.

The third pixel electrode PE3 may include a third lower electrode layer BTC3, a third reflective electrode layer RE3, and a third upper electrode layer UTC3. The third reflective electrode layer RE3 may be arranged on the third lower electrode layer BTC3, and the third upper electrode layer UTC3 may be sequentially arranged on the third reflective electrode layer RE3.

In one or more embodiments, a thickness of each of the first, second, and third lower electrode layers BTC1, BTC2, and BTC3 may be substantially the same. For example, each of the first, second, and third lower electrode layers BTC1, BTC2, and BTC3 may have substantially the same thickness and be spaced and/or apart (e.g., spaced apart or separated) from each other on the via layer VIA.

The first lower electrode layer BTC1 may be arranged along a profile of the first groove HM1 and the first contact hole HL1, and the second lower electrode layer BTC2 may be arranged along a profile of the second groove HM2 and the first contact hole HL1, and the third lower electrode layer BTC3 may be arranged along a profile of the third groove HM3 and the third contact hole HL3.

In one or more embodiments, the first, second, and third lower electrode layers BTC1, BTC2, and BTC3 may include indium (In) and tin (Sn). The first, second, and third lower electrode layers BTC1, BTC2, and BTC3 may include transparent conductive oxide. However, embodiments of the present disclosure are not necessarily limited thereto.

The first, second, and third reflective electrode layers RE1, RE2, and RE3 may be arranged along a profile of the first, second, and third lower electrode layers BTC1, BTC2, and BTC3, respectively. For example, the first reflective electrode layer RE1 may extend into the first contact hole HL1. The second reflective electrode layer RE2 may extend into the second contact hole HL2. The third reflective electrode layer RE3 may extend into the third contact hole HL3.

In one or more embodiments, a thickness of each of the first, second, and third reflective electrode layers RE1, RE2, and RE3 may be substantially the same. For example, each of the first, second, and third reflective electrode layers RE1, RE2, and RE3 may have substantially the same thickness and may be arranged on the first, second, and third lower electrode layers BTC1, BTC2, and BTC3 respectively. However, embodiments of the present disclosure are not necessarily limited thereto. Each of the first, second, and third reflective electrode layers RE1, RE2, and RE3 may have different thicknesses.

The first, second, and third upper electrode layers UTC1, UTC2, and UTC3 may be arranged on the first, second, and third reflective electrode layers RE1, RE2, and RE3 respectively. The first, second, and third upper electrode layers UTC1, UTC2, and UTC3 may include substantially the same material as the first, second, and third lower electrode layers BTC1, BTC2, and BTC3. In some embodiments, the first, second, and third upper electrode layers UTC1, UTC2, and UTC3 may further include other materials that are not included in the first, second, and third lower electrode layers BTC1, BTC2, and BTC3. For example, the first, second, and third upper electrode layers UTC1, UTC2, and UTC3 may be transparent conductive oxides that further include materials other than indium (In) and tin (Sn). For example, the first, second, and third upper electrode layers UTC1, UTC2, and UTC3 may include silver (Ag), magnesium (Mg), aluminum (Al), platinum (Pt), gold (Au), nickel (Ni), chromium (Cr), and/or the like.

In one or more embodiments, a thickness of each of the first, second, and third upper electrode layers UTC1, UTC2, and UTC3 may be different. For example, as the first, second, and third depths DT1, DT2, and DT3 of each of the first, second, and third grooves HM1, HM2, and HM3 are different, the first, second, and third upper electrode layers UTC1, UTC2, UTC3 may have different thicknesses. For example, as shown in FIG. 4, a thickness of the first upper electrode layer UTC1 may be thicker than a thickness of each of the second upper electrode layer UTC2 and the third upper electrode layer UTC3.

In one or more embodiments, with respect to the first substrate SUB1, upper surfaces of the first, second, and third upper electrode layers UTC1, UTC2, and UTC3 may have substantially the same level. For example, as the first, second, and third upper electrode layers UTC1, UTC2, and UTC3 are manufactured through substantially the same solution process, and a level of each of upper surfaces of the first, second, and third upper electrode layers UTC1, UTC2, and UTC3 may be substantially the same (e.g., equal).

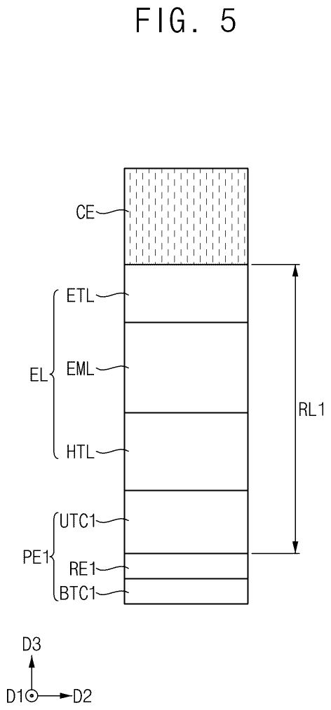

FIG. 5 is an enlarged cross-sectional view showing the first pixel electrode, the light emitting layer, and the common electrode of FIG. 3. For example, FIG. 5 is an enlarged cross-sectional view of the first pixel electrode PE1, the light emitting layer EL, and the common electrode CE shown in FIG. 3. The light emitting layer EL may be arranged on the second pixel electrode PE2 and the third pixel electrode PE3 as shown in FIG. 5. Therefore, overlapping content may not be included or may be simplified.

Referring to FIGS. 3, 4, and 5, the light emitting layer EL may include a hole transport layer HTL, a light emitting material layer EML, and an electron transport layer ETL. In FIG. 5, the light emitting layer EL is shown as including three components, but the embodiment of the present disclosure is not necessarily limited thereto. The light emitting layer EL may further include an electron injection layer, a hole injection layer, and/or the like

The hole transport layer HTL may be arranged on the first pixel electrode PE1. The hole transport layer HTL may inject holes into the light emitting material layer EML. The light emitting layer EL may include a plurality of hole transport layers. The hole transport layer HTL may include one or more suitable organic substances including copper phthalocyanine (CuPc: copper phthalocyanine), N,N-di(naphthalene-1-yl)-N,N′-diphenyl-benzidine (N,N′-Di(naphthalene-1-yl)-N,N′-diphenyl-benzidine: NPB), and/or tris-8-hydroxyquinoline aluminum (Alq3). These may be used alone or in combination with each other. However, embodiments of the present disclosure are not necessarily limited thereto.

The light emitting material layer EML may be arranged on the hole transport layer HTL. The light emitting material layer EML may be to emit light of a preset color. The light emitting layer EL may include a plurality of light emitting material layers.

In one or more embodiments, the light emitting material layer EML may include at least one selected from among (e.g., of) a red material that emits red light, a blue material that emits blue light, and a green material that emits green light. For example, the light emitting layer EL may include a red material, a blue material, and a green material. For example, the light emitting layer EL may be to emit white light that is a mixture of red, blue, and green. For another example, the light emitting layer EL may be to emit blue light. However, embodiments of the present disclosure are not necessarily limited thereto.

In one or more embodiments, a first distance RL1 may be defined as a distance between the first reflective electrode layer RE1 and the common electrode CE in a cross-sectional view. Some of light emitted from the light emitting layer EL may pass through the common electrode CE. However, a first light, which is another part of the light emitted from the light emitting layer EL, may be reflected by the common electrode CE in a direction opposite to the third direction D3 and the first light may be reflected again by the reflective electrode layer RE1.

Likewise, a portion of the first light reflected by the first reflective electrode layer RE1 may pass through the common electrode CE, but a second light, which is another portion of the first light, may be reflected by the common electrode CE and reflected again by the first reflective electrode layer RE1. Accordingly, the first light and the second light may form a standing wave between the common electrode CE and the first reflective electrode layer RE1 in a cross-sectional view. As the first light and the second light form a standing wave, a third light having a greater intensity than the first light and the second light may be formed.

As shown in FIGS. 3 and 5, the constructive interfered third light passes through the first color conversion layer CCL1 and passes through a first color filter CF1 that selectively transmits the first color. For example, if a wavelength of the third light with increased light intensity matches a wavelength band of the first color, a luminous efficiency of the display device DD may be increased. Because the third light undergoes constructive interference within the first distance RL1 in a cross-sectional view, the first distance RL1 may have a certain relationship with a size of the wavelength of the third light. For example, in order to increase a luminous efficiency of the display device DD, a wavelength band of the first color matching the wavelength of the third light and the first distance RL1, which is a resonance distance, may have a certain relational expression.

As a result, the first distance RL1 and a wavelength of the first color may satisfy Equation 1.

$$L = ( λ / 2 ) \times N \qquad Equation 1$$

In Equation 1, L is a resonance distance (e.g., the first distance RL1 in FIG. 5), A is a middle value of the wavelength band of the first color, and N is a natural number.

Referring to Equation 1, when the first color is red, a wavelength range is from about 610 nanometer (nm) to about 700 nm, so λ may be about 655 nm, e.g., that may be a middle value of the wavelength band), and a resonance distance L may be an integer multiple of about 377.5 nm.

Referring to Equation 1, when the first color is green, a wavelength range is from about 500 nm to about 570 nm, so λ may be about 535 nm that is a middle value of the wavelength band, and a resonance distance L may be an integer multiple of about 267.5 nm.

Referring to Equation 1, when the first color is blue, a wavelength range is from about 450 nm to about 500 nm, so λ may be about 475 nm that is a middle value of the wavelength band, and a resonance distance L may be an integer multiple of about 237.5 nm.

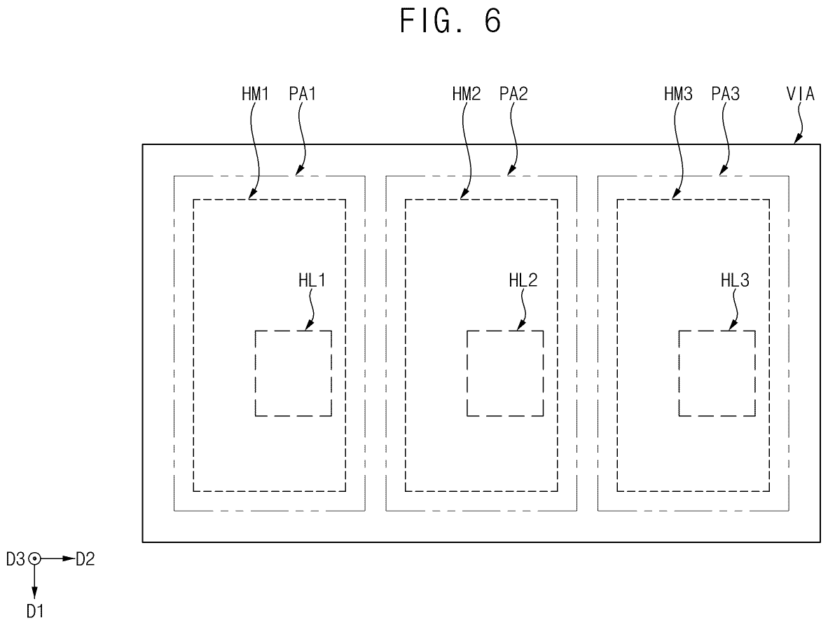

FIG. 6 is a plan view showing an example of the via layer of FIG. 3.

Referring to FIGS. 3 and 6, the first contact hole HL1 may overlap the first groove HM1 in a plan view, the second contact hole HL2 may overlap the second groove HM2 in a plan view, and the third contact hole HL3 may overlap the third groove HM3 in a plan view.

For example, the first contact hole HL1 may be exposed by the first groove HM1 and may penetrate the via layer VIA. The second contact hole HL2 is exposed by the second groove HM2 and may penetrate the via layer VIA. The third contact hole HL3 is exposed by the third groove HM3 and may penetrate the via layer VIA.

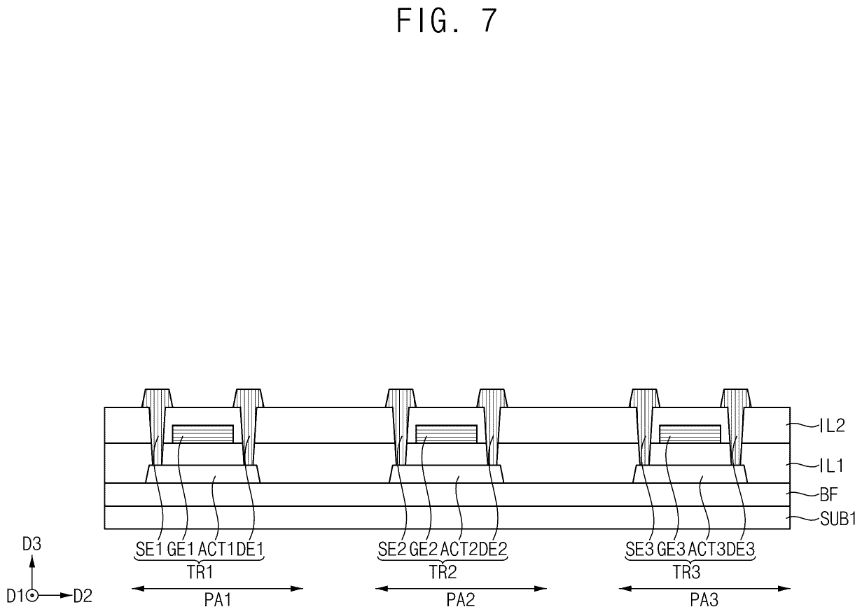

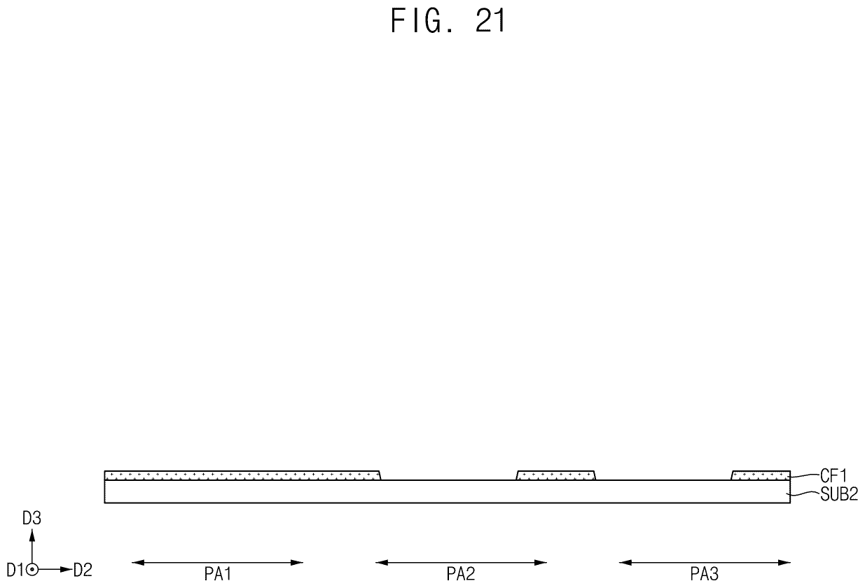

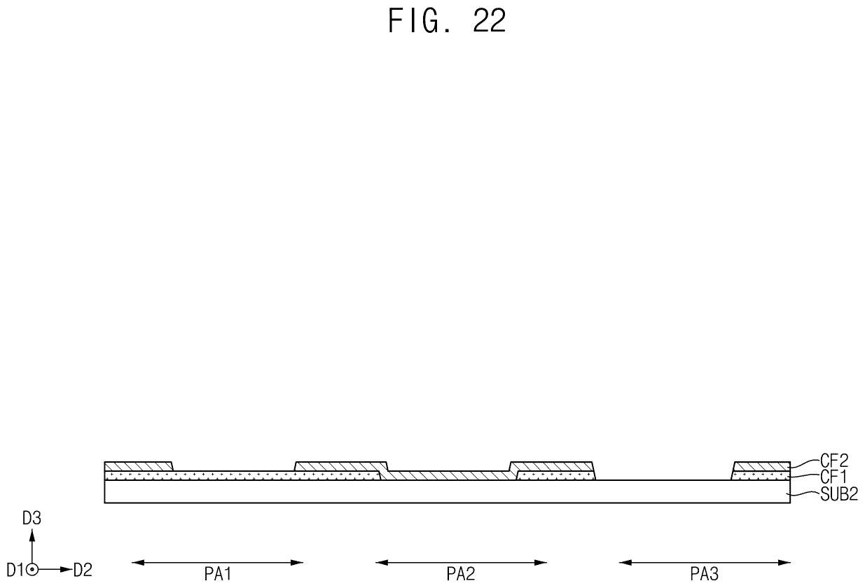

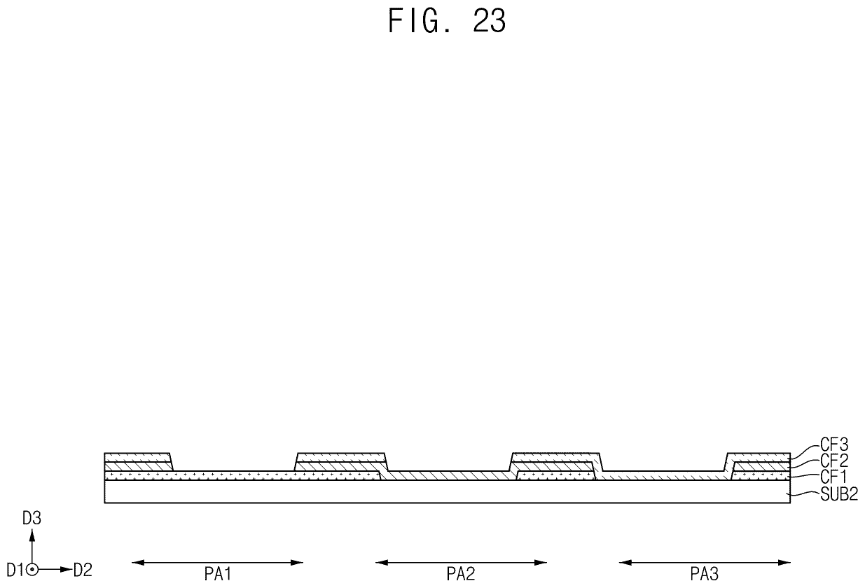

FIGS. 7 to 28 are cross-sectional views showing a method of manufacturing the display device of FIG. 3. For example, a manufacturing method of forming from the first substrate SUB1 to the encapsulation layer ENC will be described with reference to FIGS. 7 to 20. A manufacturing method of forming from the second substrate SUB2 to the second capping layer CL2 will be described with reference to FIGS. 21, 22, 23, 24, 25, 26 and 27.

Referring to FIG. 7, the first transistor TR1 may be formed in the first pixel area PA1, the second transistor TR2 may be formed in the second pixel area PA2, and the third transistor TR3 may be formed in the third pixel area PA3. The first active layer ACT1 of the first transistor TR1, the second active layer ACT2 of the second transistor TR2, and the third active layer ACT3 of the third transistor TR3 may be formed on a same layer.

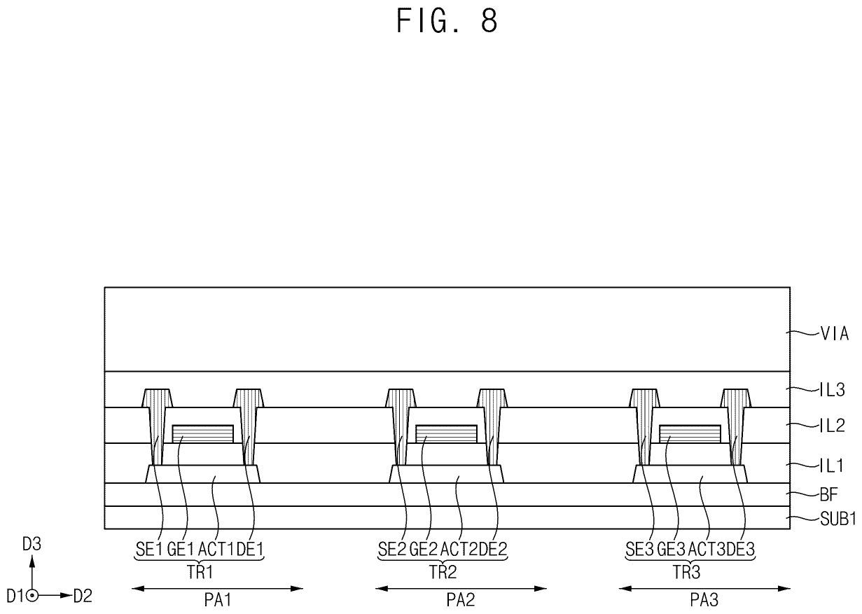

Referring further to FIG. 8, the third insulating layer IL3 and the via layer VIA may be sequentially formed on the second insulating layer IL2. The third insulating layer IL3 may cover the first transistor TR1, the second transistor TR2, and a portion of the third transistor TR3 and may be formed on the second insulating layer IL2.

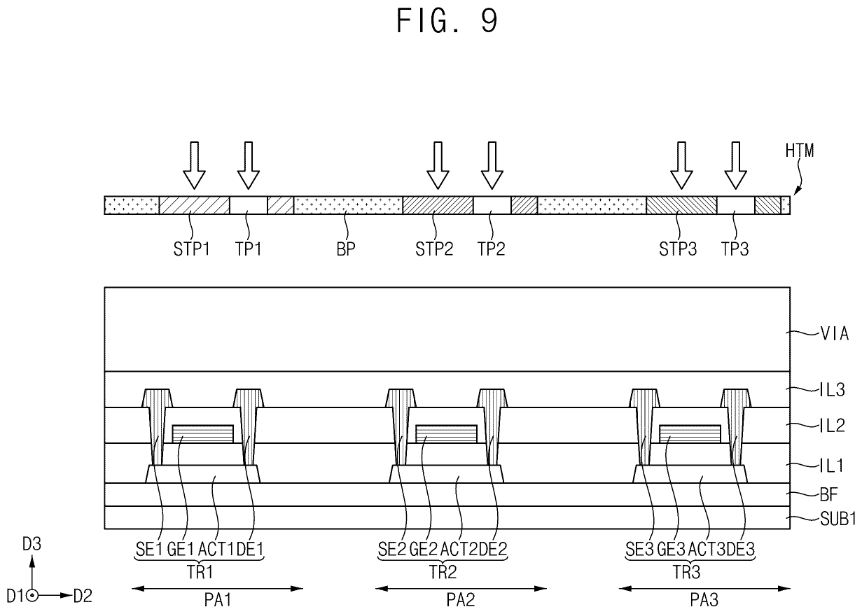

Referring further to FIG. 9, a halftone mask HTM may be arranged on the via layer VIA. In the halftone mask HTM, a first transmissive portion TP1 and a first semi-transmissive portion STP1 may be defined (e.g., included) in an area corresponding to the first pixel area PA1, a second transmissive portion TP2 and a second semi-transmissive portion STP2 may be defined (e.g., included) in an area corresponding to the second pixel area PA2, and a third transmissive portion TP3 and a third semi-transmissive portion STP3 may be defined (e.g., included) in an area corresponding to the third pixel area PA3. A light blocking part BP may be defined (e.g., included) where the first, second, and third transmissive portions TP1, TP2, and TP3 and the first, second, and third semi-transmissive portions STP1, STP2, and STP3 are not defined (e.g., excluded).

In one or more embodiments, the third semi-transmissive portion STP3 may not be included. For example, the first semi-transmissive portion STP1 and the second semi-transmissive portion STP2 may be defined (e.g., included) in the first pixel area PA1 and the second pixel area PA2 respectively, but the third semi-transmissive portion STP3 may not be included. For example, only the third transmissive portion TP3 may be defined (e.g., included) in an area corresponding to the third pixel area PA3, and the third semi-transmissive portion STP3 may not be defined (e.g., excluded).

In one or more embodiments, a transmittance of each of the first semi-transmissive portion STP1, the second semi-transmissive portion STP2, and the third semi-transmissive portion STP3 may be different. For example, a magnitude of a transmittance of the first semi-transmissive portion STP1 may be greater than a magnitude of a transmittance of the second semi-transmissive portion STP2, and a magnitude of a transmittance of the second semi-transmissive portion STP2 may be greater a magnitude of a transmittance of the third semi-transmissive portion STP3. However, embodiments of the present disclosure are not necessarily limited thereto.

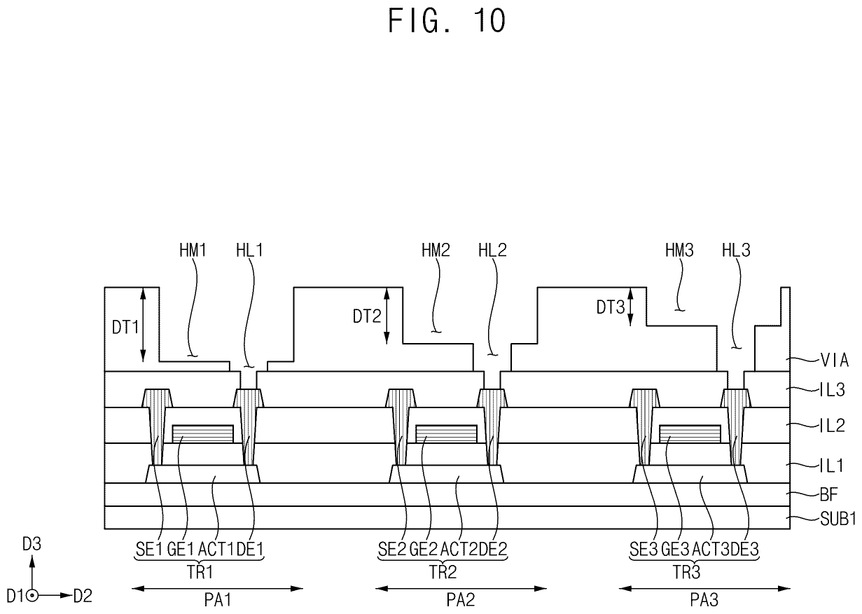

Referring further to FIGS. 9 and 10, an exposure process may be performed on the via layer VIA in response to the halftone mask HTM. In the first pixel area PA1 of the via layer VIA, the first groove HM1 corresponding to the first semi-transmissive portion STP1 and the first contact hole HL1 corresponding to the first transmissive portion TP1 may be formed. In the second pixel area PA2 of the via layer VIA, the second groove HM2 corresponding to the second semi-transmissive portion STP2 and the second contact hole HL2 corresponding to the second transmissive portion TP2 may be formed. In the third pixel area PA3 of the via layer VIA, the third groove HM3 corresponding to the third semi-transmissive portion STP3 and the third contact hole HL3 corresponding to the third transmissive portion TP3 may be formed.

The first contact hole HL1 may expose at least a portion of an upper surface of the first drain electrode DE1 of the first transistor TR1. The second contact hole HL2 may expose at least a portion of an upper surface of the second drain electrode DE2 of the second transistor TR2. The third contact hole HL3 may expose at least a portion of an upper surface of the third drain electrode DE3 of the third transistor TR3.

In one or more embodiments, the first depth DT1 of the first groove HM1, the second depth DT2 of the second groove HM2, and the third depth DT3 of the third groove HM3 in a cross-sectional view may be formed differently. For example, as a transmittance of the first semi-transmissive portion STP1, a transmittance of the second semi-transmissive portion STP2, and a transmittance of the third semi-transmissive portion STP3 may be different, the first depth DT1, the second depth DT2, and the third depth DT3 may be formed differently. Accordingly, a depth of each of the first contact hole HL1, the second contact hole HL2, and the third contact hole HL3 may be formed differently.

In one or more embodiments, the first groove HM1 and the first contact hole HL1 may be formed (e.g., substantially) simultaneously. The second groove HM2 and the second contact hole HL2 may be formed (e.g., substantially) simultaneously. The third groove HM3 and the third contact hole HL3 may be formed (e.g., substantially) simultaneously. For example, the first, second, and third grooves HM1, HM2, and HM3 and the first, second, and third contact holes HL1, HL2, and HL3 may be formed (e.g., substantially) simultaneously in a single (e.g., one-step) process by the halftone mask HTM shown in FIG. 9. For example, as the grooves HM1, HM2, and HM3 and the contact holes HL1, HL2, and HL3 are simultaneously etched and formed through the halftone mask HTM, manufacturing costs may be reduced by simplifying a manufacturing process rather than manufacturing the contact holes HL1, HL2, and HL3 separately.

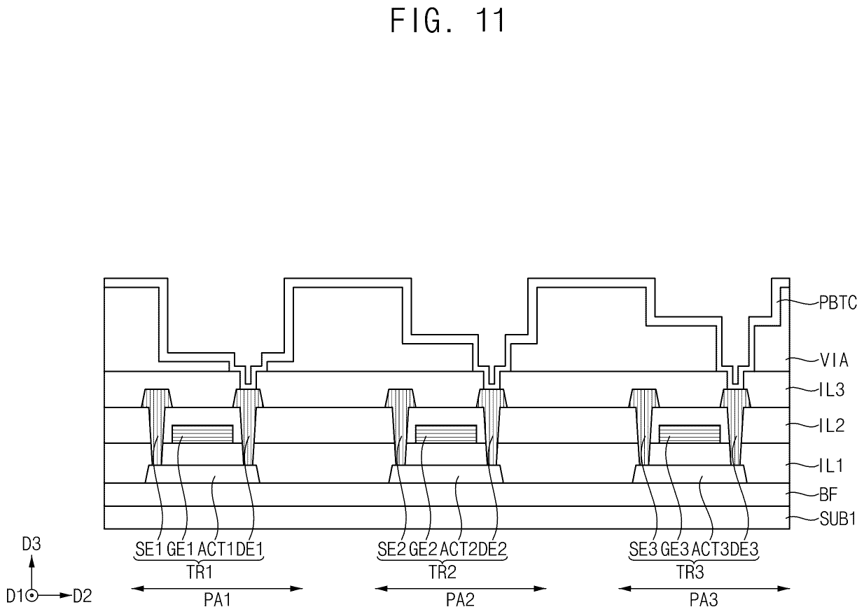

Referring further to FIG. 11, a preliminary lower electrode layer PBTC may be formed on the via layer VIA. The preliminary lower electrode layer PBTC may be formed continuously without interruption on the via layer VIA. For example, the preliminary lower electrode layer PBTC may be formed on the via layer VIA through a sputtering method. Accordingly, the preliminary lower electrode layer PBTC may be formed to have a uniform thickness on the via layer VIA. The preliminary lower electrode layer PBTC may include substantially the same material as the first lower electrode layer (e.g., the first lower electrode layer BTC1 in FIG. 4).

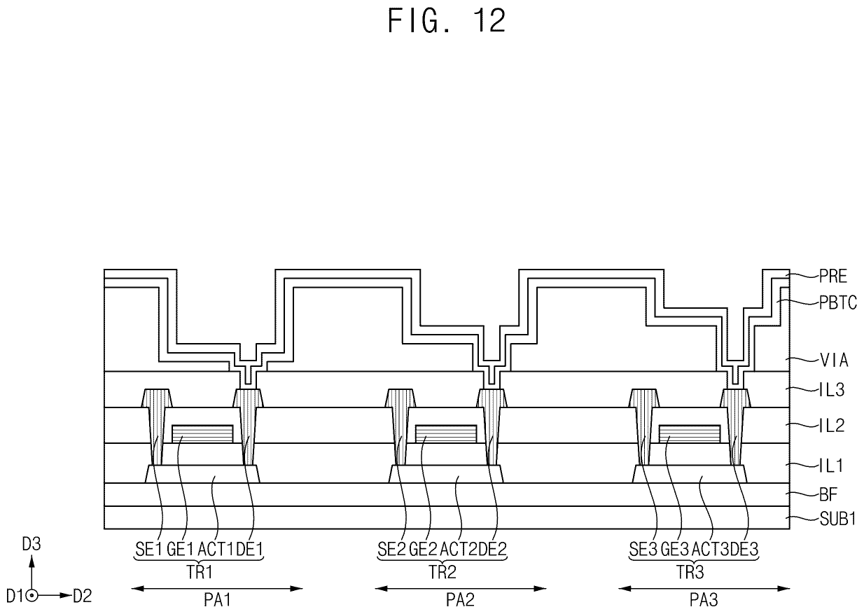

Referring further to FIG. 12, a preliminary reflective electrode layer PRE may be formed on the preliminary lower electrode layer PBTC. The preliminary reflective electrode layer PRE may be formed continuously without interruption on the preliminary lower electrode layer PBTC. For example, the preliminary reflective electrode layer PRE may be formed on the preliminary lower electrode layer PBTC through a sputtering method. Accordingly, the preliminary reflective electrode layer PRE may be formed to have a uniform thickness on the preliminary lower electrode layer PBTC. The preliminary reflective electrode layer PRE may include substantially the same material as the first reflective electrode layer (e.g., the first reflective electrode layer RE1 in FIG. 4).

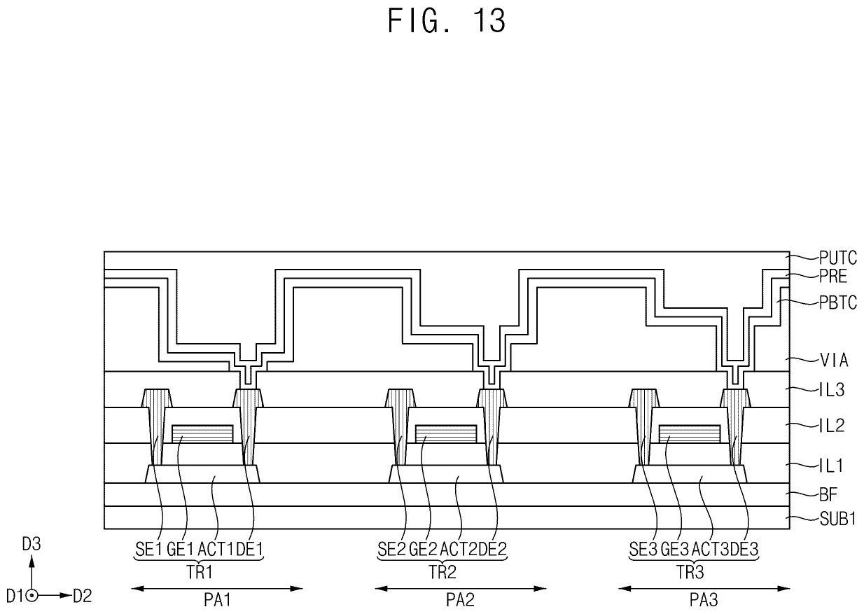

Referring further to FIG. 13, a preliminary upper electrode layer PUTC may be formed on the preliminary reflective electrode layer PRE. The preliminary upper electrode layer PUTC may be formed on the preliminary reflective electrode layer PRE through a solution process method. By forming the preliminary upper electrode layer PUTC on the preliminary reflective electrode layer PRE through the solution process method, an upper surface of the preliminary upper electrode layer PUTC may be formed to be (e.g., substantially) flat.

In one or more embodiments, a level of an upper surface of the preliminary upper electrode layer PUTC with respect to the first substrate SUB1 may be higher than a level of an (e.g., any) upper surface of the via layer VIA. For example, as the preliminary upper electrode layer PUTC is formed on the via layer VIA by a solution process, so that a level of an upper surface of the preliminary upper electrode layer PUTC may be higher than a level of an (e.g., any) upper surface of the via layer VIA.

For example, the preliminary upper electrode layer PUTC may include substantially the same material as the preliminary lower electrode layer PBTC. For another example, the preliminary upper electrode layer PUTC may further include a material different from a material included in the preliminary lower electrode layer PBTC.

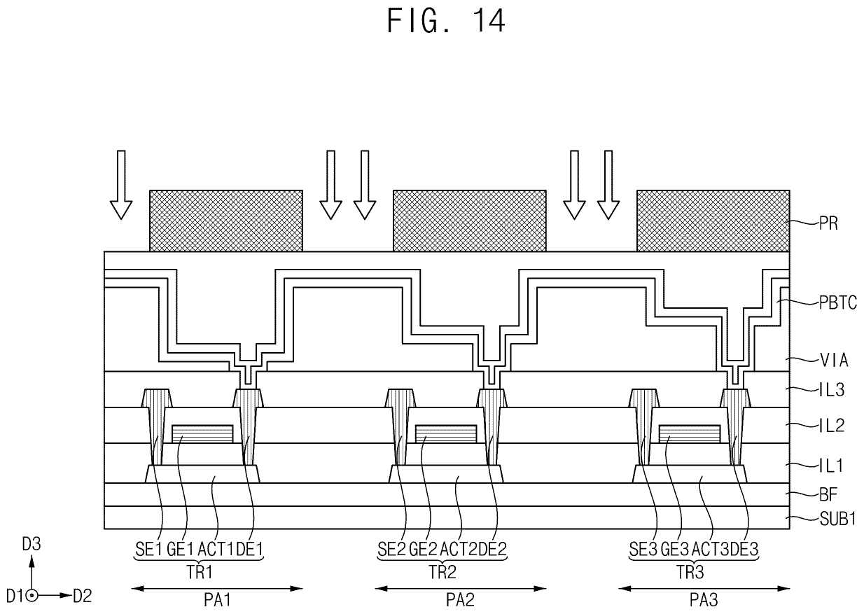

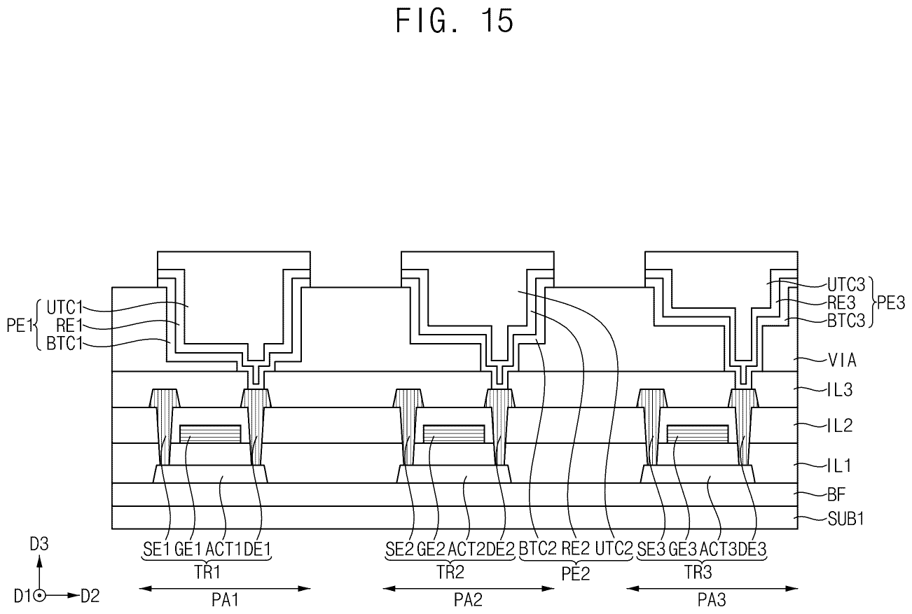

Referring further to FIGS. 14 and 15, the photoresist PR may be formed overlapping the first pixel area PA1, the second pixel area PA2, and the third pixel area PA3 in a plan view. The photoresist PR may be an anti-etching layer.

As shown in FIG. 14, the preliminary lower electrode layer PBTC, the preliminary reflective electrode layer PRE, and the preliminary upper electrode layer PUTC may be etched except for a portion where the photoresist PR is formed. Accordingly, as shown in FIG. 15, the first pixel electrode PE1, the second pixel electrode PE2, and the third pixel electrode PE3 may be formed. The first pixel electrode PE1, the second pixel electrode PE2, and the third pixel electrode PE3 may be formed (e.g., substantially) simultaneously.

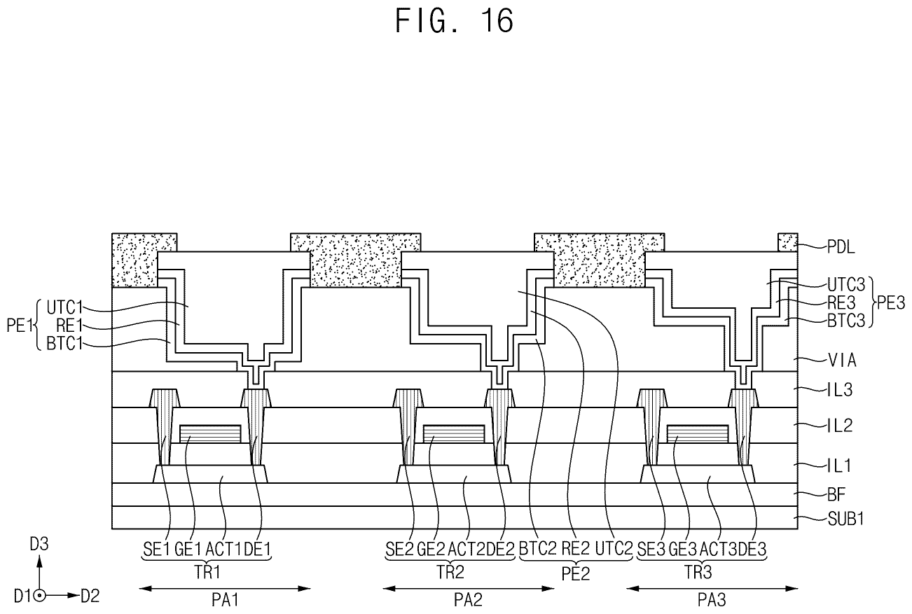

Referring further to FIG. 16, the pixel defining layer PDL may be formed between the first pixel electrode PE1, the second pixel electrode PE2, and the third pixel electrode PE3. The pixel defining layer PDL may be formed to cover at least a portion of each of the first pixel electrode PE1, the second pixel electrode PE2, and the third pixel electrode PE3. For example, the pixel defining layer PDL may be formed while exposing at least a portion of an upper surface of each of the first pixel electrode PE1, the second pixel electrode PE2, and the third pixel electrode PE3.

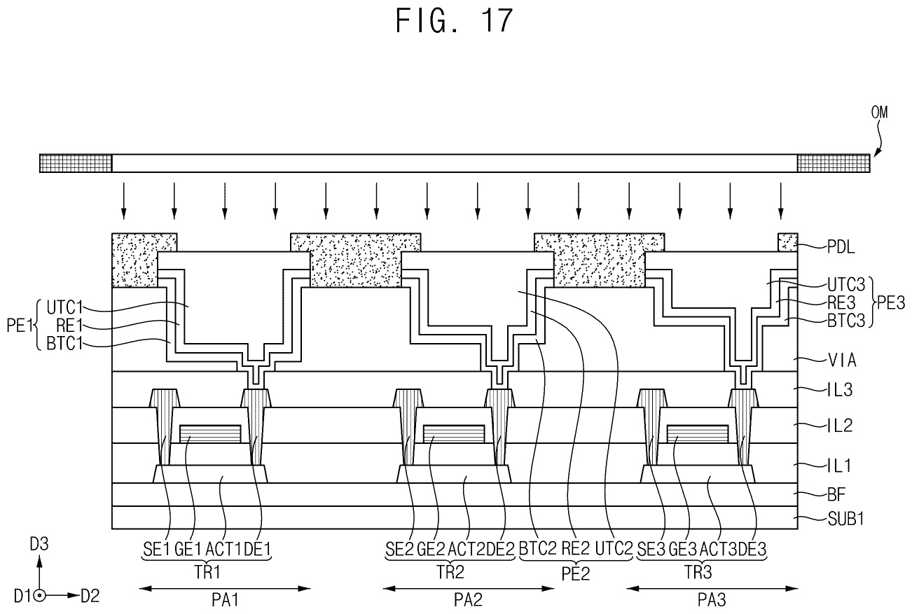

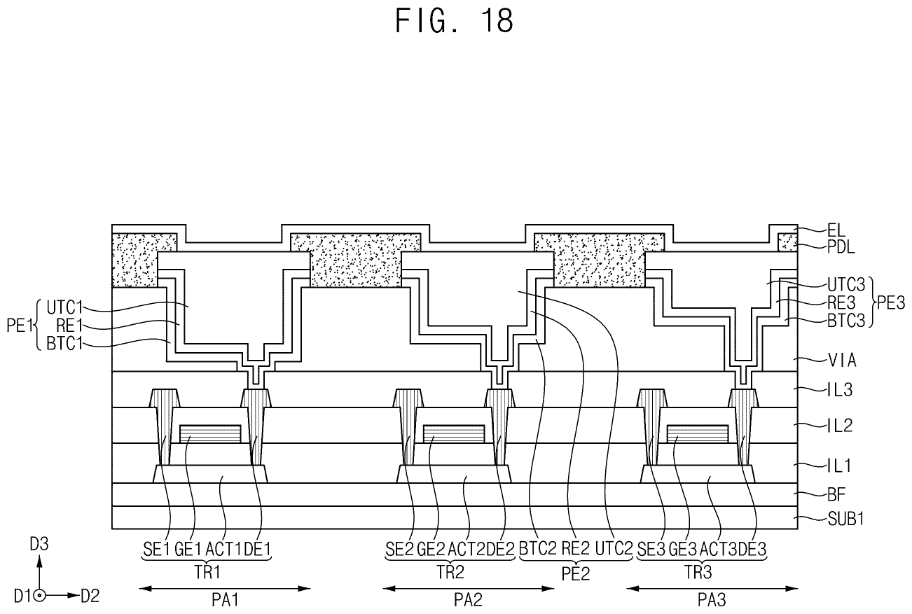

Referring further to FIGS. 17 and 18, an open mask OM may be arranged on the first, second, and third pixel electrodes PE1, PE2, and PE3 and the pixel defining layer PDL. The light emitting layer EL may be formed by disposing the open mask OM on the first, second, and third pixel electrodes PE1, PE2, and PE3 and the pixel defining layer PDL. As the light emitting layer EL is formed by the open mask OM, the light emitting layer EL may be formed (e.g., substantially) continuously on the first, second, and third pixel electrodes PE1, PE2, and PE3, as shown in FIG. 18. The light emitting layer EL may be formed to have a (e.g., substantially) uniform thickness.

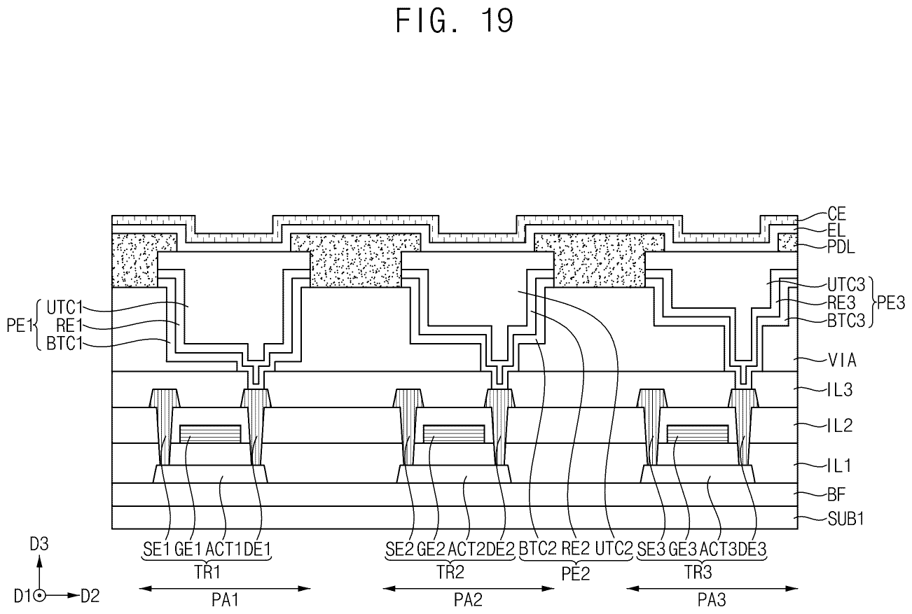

Referring further to FIG. 19, the common electrode CE may be formed on the light emitting layer EL. The common electrode CE may be formed continuously without interruption on the light emitting layer EL. The common electrode CE may be formed to have a (e.g., substantially) uniform thickness on the light emitting layer EL. For example, the common electrode CE may be a plate electrode with a (e.g., substantially) uniform thickness.

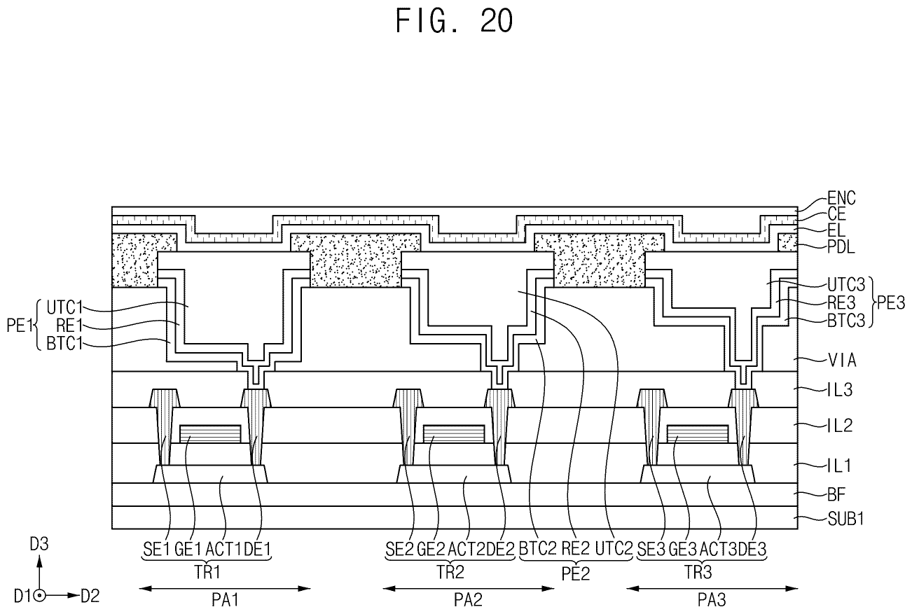

Referring further to FIG. 20, the encapsulation layer ENC may be formed on the common electrode CE. An upper surface of the encapsulation layer ENC may be formed to be (e.g., substantially) flat. The encapsulation layer ENC may include at least one inorganic encapsulation layer and/or at least one organic encapsulation layer.

Referring further to FIGS. 21, 22, and 23, the first, second, and third color filters CF1, CF2, and CF3 may be formed on the second substrate SUB2.

The first color filter CF1 may be formed to overlap the first pixel area PA1. The first color filter CF1 may also be formed in an area that does not overlap the second pixel area PA2 and the third pixel area PA3. The first color filter CF1 may be a red color filter that transmits red light.

The second color filter CF2 may be formed to overlap the second pixel area PA2. The second color filter CF2 may be formed on at least a portion of the first color filter CF1. The second color filter CF2 may be a green color filter that transmits green light.

The third color filter CF3 may be formed to overlap the third pixel area PA3. The third color filter CF3 may be formed to overlap the first color filter CF1 and/or the second color filter CF2. The third color filter CF3 may be a blue color filter that transmits blue light.

Accordingly, only the first color filter CF1 may be formed in at least a portion of the first pixel area PA1 of the second substrate SUB2. Only the second color filter CF2 may be formed in at least a portion of the second pixel area PA2 of the second substrate SUB2. Only the third color filter CF3 may be formed in at least a portion of the third pixel area PA3 of the second substrate SUB2.

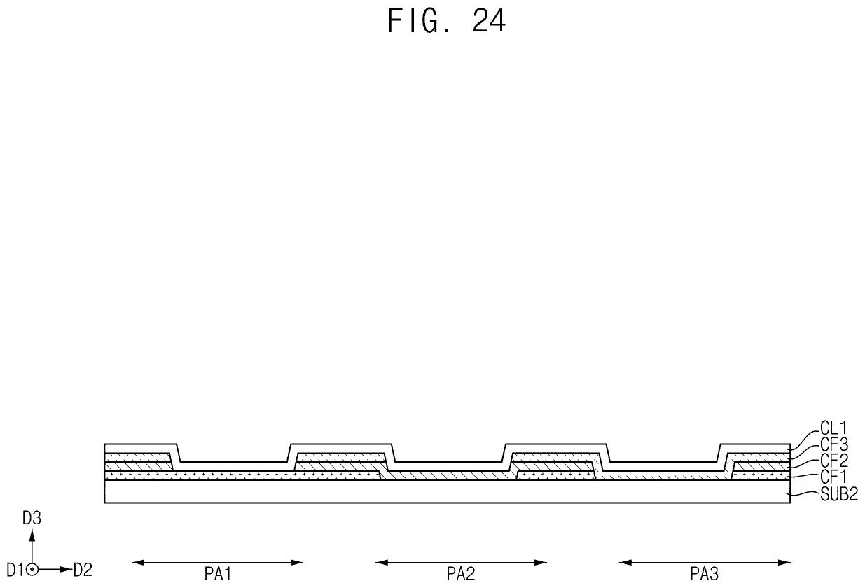

Referring further to FIG. 24, the first capping layer CL1 may be formed on the color filters CF1, CF2, and CF3. The first capping layer CL1 may cover the color filters CF1, CF2, and CF3. The first capping layer CL1 may be formed along a profile of each of an upper surfaces of the color filters CF1, CF2, and CF3. For example, the first capping layer CL1 may be formed using an inorganic material.

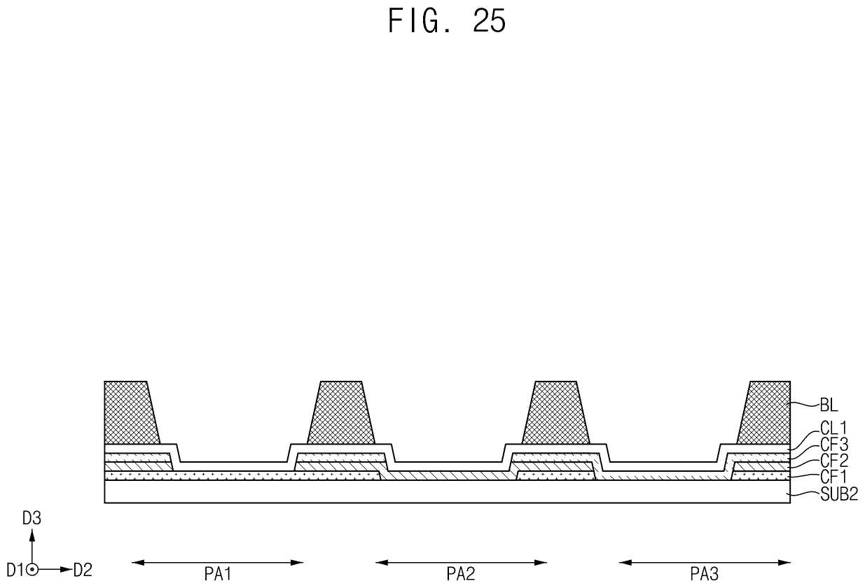

Referring to further FIG. 25, the light blocking member BL may be formed between the first pixel area PA1 and the second pixel area PA2. In some embodiments, the light blocking member BL may be formed between the second pixel area PA2 and the third pixel area PA3.

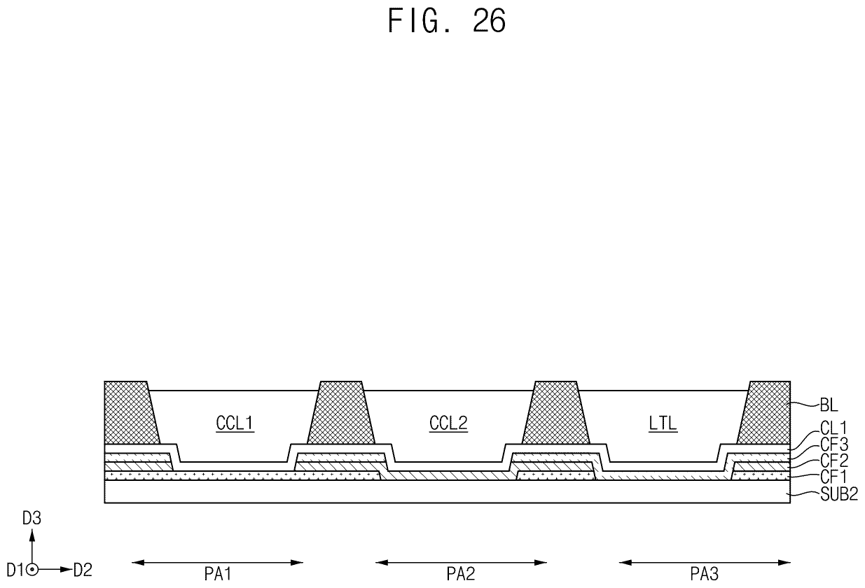

Referring to further FIG. 26, the first color conversion layer CCL1 may be formed in an opening defined by (e.g., included in) the light blocking member BL and overlapping the first pixel area PA1. The second color conversion layer CCL2 may be formed in an opening defined by the light blocking member BL and overlapping the second pixel area PA2. The light transmissive layer LTL may be formed in an opening defined by (e.g., included in) the light blocking member BL and overlapping the third pixel area PA3.

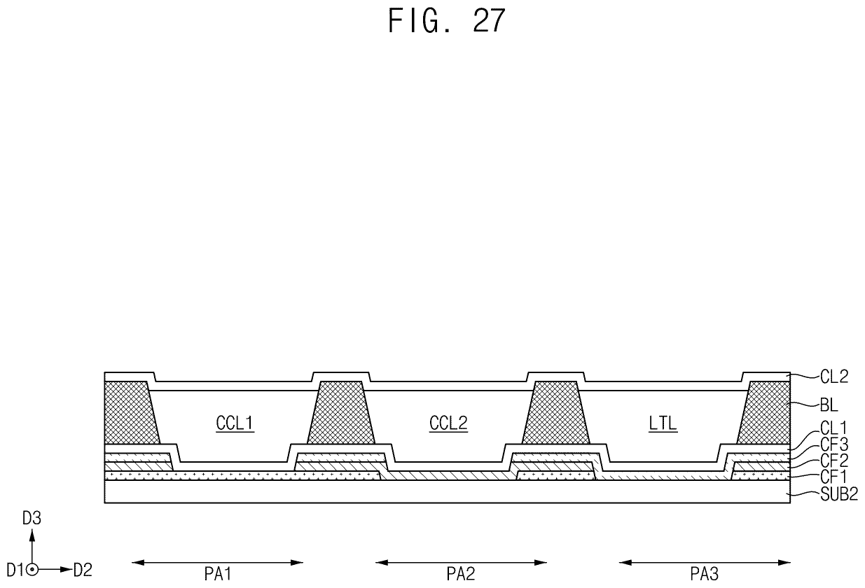

Referring to further FIG. 27, the second capping layer CL2 may be formed on the first color conversion layer CCL1, the second color conversion layer CCL2, the light transmissive layer LTL, and the light blocking member BL. The second capping layer CL2 may cover the light blocking member BL, the first color conversion layer CCL1, the second color conversion layer CCL2, and the light transmissive layer LTL. For example, the second capping layer CL2 may be formed using an inorganic material.

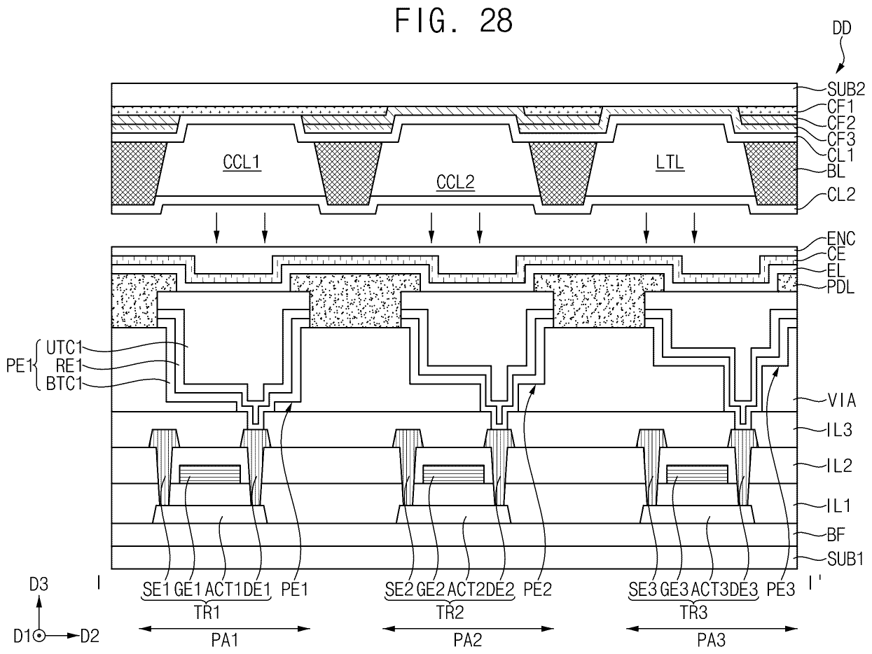

Referring to further FIG. 28, the encapsulation layer ENC and the second capping layer CL2 may be combined through the filling layer (e.g., the filling layer FL in FIG. 3). As a result, the display device (e.g., the display device DD in FIG. 3) including the first substrate SUB1 and the second substrate SUB2 facing the first substrate SUB1 may be formed.

According to one or more embodiments of the present disclosure, the display device may be included in one or more electronic devices. In one or more embodiments, the electronic devices may be smartphones, high-resolution smartphones, mobile phones, smart pads, smart watches, tablet PCs, electric vehicles, vehicle navigation systems, televisions, computer monitors, laptop computers, mobile communication terminals, electronic notebooks, portable multimedia players (PMPs), ultra-mobile PC (UMPCs), computers, billboards, Internet of Things (IoT) devices, watch phones, head-mounted displays (HMDs), and/or the like.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or ±30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display device may be formed on one integrated circuit (IC) chip or on separate IC chips. Further, the one or more suitable components of the display device may be implemented on a flexible printed circuit film, a tape carrier package (TCP), a printed circuit board (PCB), or formed on one substrate. Further, the one or more suitable components of the display device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

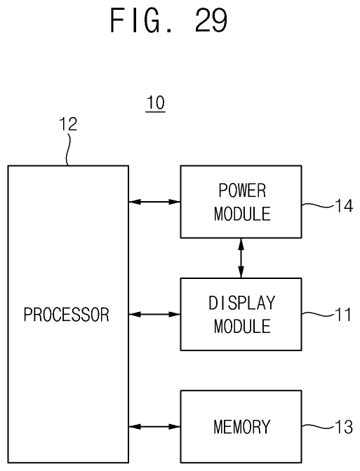

FIG. 29 is a block-diagram showing an electronic device according to an embodiment of the present disclosure.

Referring to FIGS. 1 and 29, the display device DD according to the embodiments may be applied to one or more suitable electronic devices 10. The electronic device 10 according to an embodiment includes the display device DD described herein, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor CP, an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may convert a power supply module such as a power adapter or a battery device and the power supplied by the power supply module. Specifically, the power module 14 may include a power conversion module that generates power required for the operation of the electronic device 10.

At least one of the components of the electronic device 10 described herein may be included in the display device according to the embodiments described herein. In addition, some of the individual modules functionally included in one module may be included in the display device, and others may be provided separately from the display device. For example, the display device DD may include the display module 11, and the processor 12, the memory 13, and the power module 14 may be provided in the form of other devices within the electronic device 10 other than the display device DD.

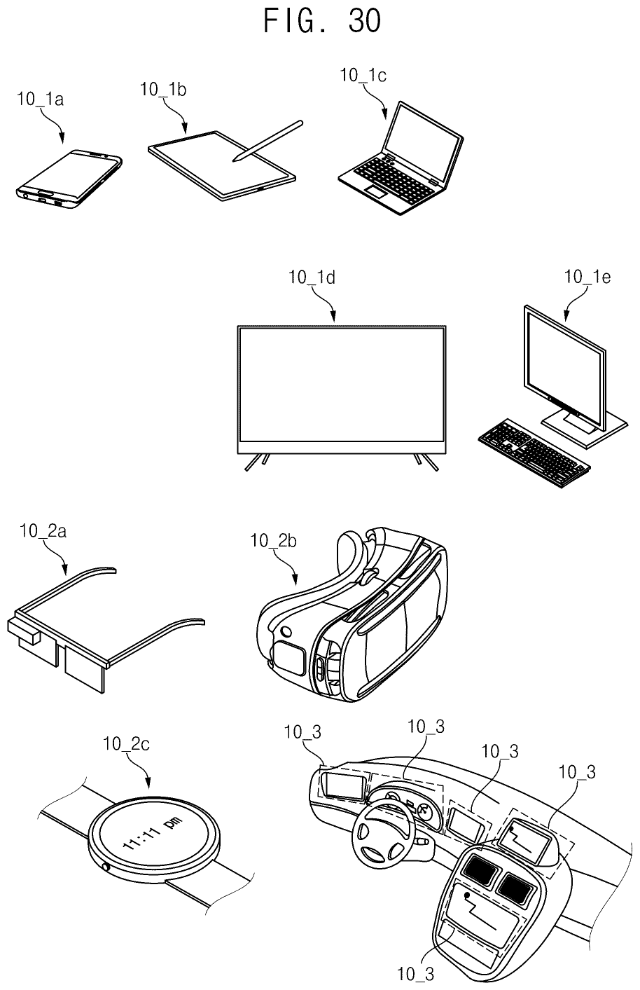

FIG. 30 is schematic views of the electronic devices according to one or more suitable embodiments of FIG. 29.

Referring to FIGS. 29 and 30, one or more suitable electronic devices 10 to which the display device DD according to the embodiments is applied may include electronic devices for displaying images, such as a smart phone 10_1a, a tablet PC 10_1b, a laptop 10_1c, a TV 10_1d, and a desk monitor 10_1e. In addition, it may include wearable electronic devices including display modules such as smart glasses 10_2a, head mounted displays 10_2b, smart watches 10_2c, and vehicle electronic devices 10_3 including display modules such as CID (Center Information Display) and room mirror displays disposed on the instrument panel, center fascia, and dashboard of a car.

However, the preceding are merely examples, and the electronic device 10 according to embodiments of the present disclosure is not necessarily limited thereto. For example, the electronic device 10 may be implemented as a mobile phone, a video phone, a smart pad, a smart watch, a tablet PC, a vehicle display, a computer monitor, a notebook, a head mounted display device, etc. In addition, the electronic device 10 may be a television, a monitor, a notebook computer, or a tablet. In addition, the electronic device 10 may be a car.

While the subject matter of the disclosure has been particularly shown and described with reference to embodiments thereof, it will be understood by those of ordinary skill in the art that one or more suitable changes in form and details may be made therein without departing from the spirit or scope of the disclosure as defined by the following claims, and equivalents thereof.

What is claimed is:

1. A display device comprising:
a substrate comprising a first pixel area and a second pixel area adjacent to the first pixel area;
a via layer on the substrate and comprising
a first groove overlapping the first pixel area and having a first depth, and
a second groove overlapping the second pixel area and having a second depth different from the first depth;
a first pixel electrode in the first groove of the via layer and wherein a level of an upper surface of the first pixel electrode is higher than a level of an upper surface of the via layer with respect to the substrate;
a second pixel electrode in the second groove of the via layer, having a thickness, wherein the thickness is different from a thickness of the first pixel electrode, and wherein a level of an upper surface of the second pixel electrode is higher than a level of an upper surface of the via layer with respect to the substrate; and
a light emitting layer on the first pixel electrode and the second pixel electrode.

2. The display device of claim 1, wherein the first pixel electrode comprises a first lower electrode layer, a first reflective electrode layer, and a first upper electrode layer sequentially on the substrate, and
the second pixel electrode comprises a second lower electrode layer, a second reflective electrode layer, and a second upper electrode layer sequentially on the substrate.

3. The display device of claim 2, wherein a thickness of the first upper electrode layer and a thickness of the second upper electrode layer are different.

4. The display device of claim 2, wherein with respect to the substrate, a level of an upper surface of the first upper electrode layer is equal to a level of an upper surface of the second upper electrode layer.

5. The display device of claim 2, wherein the first upper electrode layer and the first lower electrode layer each comprise a same material.

6. The display device of claim 2, wherein the first upper electrode layer and the second upper electrode layer each comprise a transparent conductive oxide comprising at least one selected from the group consisting of indium (In) and tin (Sn).

7. The display device of claim 2, further comprising:
a common electrode on the light emitting layer and comprising a plate electrode.

8. The display device of claim 7, further comprising:
a first color conversion layer on the common electrode, overlapping the first pixel electrode, and configured to convert light emitted from the light emitting layer into a light having a first color; and
a second color conversion layer on the common electrode, overlapping the second pixel electrode, and configured to convert light emitted from the light emitting layer into a light having a second color,
wherein the second color is different from the first color.

9. The display device of claim 8, wherein a resonance distance between the common electrode and the first reflective electrode layer satisfies Equation 1:
$$L = ( λ / 2 ) \times N \qquad Equation 1$$
wherein, L is the resonance distance, A is a median value of a wavelength band of the first color, and N is a natural number.

10. The display device of claim 2, wherein a thickness of the first lower electrode layer is equal to a thickness of the second lower electrode layer.

11. The display device of claim 2, wherein the via layer comprises:
a first contact hole exposed by the first groove and penetrating the via layer; and
a second contact hole exposed by the second groove, penetrating the via layer, and having a depth different from a depth of the first contact hole.

12. The display device of claim 11, wherein the first reflective electrode layer of the first pixel electrode extends into the first contact hole, and
the second reflective electrode layer of the second pixel electrode extends into the second contact hole.

13. The display device of claim 1, wherein the light emitting layer comprises a light emitting material configured to emit white light or blue light.

14. A method comprising:
forming a via layer on a substrate, the substrate comprising a first pixel area and a second pixel area adjacent to the first pixel area;
forming with a halftone mask, a first groove and a second groove,
the first groove having a first depth in the via layer overlapping the first pixel area,
the second groove having a second depth in the via layer overlapping the second pixel area,
the second depth being different from the first depth;
forming a preliminary lower electrode layer on the via layer;
forming a preliminary reflective electrode layer on the preliminary lower electrode layer;
forming a preliminary upper electrode layer on the preliminary reflective electrode layer which has a surface level that is higher than a level of an upper surface of the via layer; and
patterning the preliminary lower electrode layer, the preliminary reflective electrode layer, and the preliminary upper electrode layer to form a first pixel electrode in the first pixel area and a second pixel electrode in the second pixel area,
wherein the method is a method of manufacturing a display device.

15. The method of claim 14, wherein the halftone mask comprises
a first semi-transmissive portion and a second semi-transmissive portion that transmit a portion of light;
a first transmissive portion and a second transmissive portion that transmit all light; and
light blocking part that blocks all light; and
wherein a transmittance of the first semi-transmissive portion of the halftone mask corresponding to the first groove is different from a transmittance of the second semi-transmissive portion of the halftone mask corresponding to the second groove.

16. The method of claim 15, wherein forming with the halftone mask, the first groove and the second groove comprises
forming a first contact hole exposed by the first groove and penetrating the via layer, and
forming a second contact hole exposed by the second groove, penetrating the via layer, and having a depth different from a depth of the first contact hole.

17. The method of claim 16, wherein the first contact hole is formed through the first transmissive portion and the second contact hole is formed through the second transmissive portion.

18. The method of claim 16, wherein the first groove and the first contact hole are formed simultaneously and the second groove and the second contact hole are formed simultaneously.

19. The method of claim 14, further comprising:
after forming the first pixel electrode and the second pixel electrode,
forming with an open mask, a light emitting layer on the first pixel electrode and the second pixel electrode.

20. The method of claim 14, wherein forming the preliminary upper electrode layer comprises forming the preliminary upper electrode layer through a solution process method.

21. An electronic device comprising a display device comprising:
a substrate comprising a first pixel area and a second pixel area adjacent to the first pixel area;
a via layer on the substrate and comprising
a first groove overlapping the first pixel area and having a first depth, and
a second groove overlapping the second pixel area and having a second depth different from the first depth;
a first pixel electrode in the first groove of the via layer and wherein a level of an upper surface of the first pixel electrode is higher than a level of an upper surface of the via layer with respect to the substrate;
a second pixel electrode in the second groove of the via layer, having a thickness, wherein the thickness is different from a thickness of the first pixel electrode, and wherein a level of an upper surface of the second pixel electrode is higher than a level of an upper surface of the via layer with respect to the substrate; and
a light emitting layer on the first pixel electrode and the second pixel electrode.

22. The electronic device of claim 21, wherein the electronic device is a smartphone, a high-resolution smartphone, a mobile phone, a smart pad, a smart watch, a tablet PC, an electric vehicle, a vehicle navigation system, a television, a computer monitor, a laptop computer, a mobile communication terminal, an electronic notebook, a portable multimedia player (PMP), an ultra-mobile PC (UMPC), a computer, a billboard, an Internet of Things (IoT) device, a watch phone, a head-mounted displays (HMD), and a combination thereof.
